(19) United States
(12) Patent Application Publication
(10) Pub. No.: US 2025/0294777 A1
(43) Pub. Date: Sep. 18, 2025

(54) INTEGRATED CIRCUIT DEVICE WITH MEMORY ARRAY AND SHARED GAIN ELEMENT

(71) Applicant: Intel Corporation, Santa Clara, CA (US)

(72) Inventors: Abhishek A. Sharma, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/603,595

(22) Filed: Mar. 13, 2024

(51) Int. Cl. H10B 53/40; G11C 11/22; H10B 53/30

(52) U.S. Cl. CPC H10B 53/40; G11C 11/221; G11C 11/2273; H10B 53/30

(57) ABSTRACT

Integrated circuit (IC) devices including a memory array and shared gain elements are disclosed herein. In one example, an IC device includes a plurality of memory cells over the substrate, a control line coupled with the plurality of memory cells, and a transistor (e.g., a shared gain/sense transistor) over the substrate and coupled with the plurality of memory cells, where the transistor includes a gate terminal coupled with the control line. In one such example, the shared gain/sense transistor can enable an improved signal-to-noise ratio (SNR).

### BACKGROUND

Embedded memory is important to the performance of modern system-on-a-chip (SoC) technology. Low-power and high-density embedded memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B illustrate example integrated circuit (IC) structures including a memory array and shared gain elements, in accordance with embodiments described herein.

FIGS. 2A-2D illustrate block diagrams of example IC structures including a memory array and shared gain elements.

FIGS. 3, 4A-4B, and 5-6 illustrate example circuit diagrams for various memory cell architectures that may be implemented in an IC device with a memory array and shared gain elements, in accordance with embodiments described herein.

FIG. 7 illustrates an example circuit diagram of a memory array with shared gain elements, in accordance with embodiments described herein.

FIG. 8A illustrates another example cross-sectional view of an IC device including a memory array and shared gain elements, in accordance with embodiments described herein.

FIG. 8B is an example circuit diagram of a portion of the IC structure of FIG. 8A.

FIGS. 9-15, 16A-16B, 17A-17B, and 18A-18C illustrate examples of IC structures including different transistor architectures that may be implemented as sense transistors and/or access transistors in IC structures including a memory array and shared gain elements, as described herein.

FIG. 19 is a top view of a wafer and dies that may include any of the IC structures disclosed herein, in accordance with any of the embodiments disclosed herein.

FIG. 20 is a side, cross-sectional view of an IC device that may include any of the IC structures disclosed herein, in accordance with any of the embodiments disclosed herein.

FIG. 21 is a side, cross-sectional view of an IC package that may include any of the IC structures disclosed herein, in accordance with various embodiments.

FIG. 22 is a side, cross-sectional view of an IC device assembly that may include any of the IC structures disclosed herein, in accordance with any of the embodiments disclosed herein.

FIG. 23 is a block diagram of an example computing device that includes an IC device with a memory array and shared gain elements in accordance with any of the embodiments disclosed herein.

FIG. 24 is a block diagram of an example processing device that includes an IC device with a memory array and shared gain elements in accordance with any of the embodiments disclosed herein.

### DETAILED DESCRIPTION

Disclosed herein are integrated circuit (IC) structures and devices with a memory array and shared gain elements. The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices implementing a memory array and shared gain elements as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to devices, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Some embodiments of the present disclosure may refer to dynamic random-access memory (DRAM) and in particular, embedded DRAM (eDRAM), because this type of memory has been introduced in the past to address the limitation in density and standby power of some other types of memory devices. Some examples also refer to three-dimensional (3D) memory, such as 3D DRAM. 3D memory can enable especially high-density embedded memory by vertically stacking devices over one another. In one example, one of the control lines for accessing 3D memory may be a vertical control line (e.g., a vertical bitline, wordline, or plateline) that is coupled to memory cells in multiple layers. A control line may be considered “vertical” with respect to a substrate or other support structure, e.g., if the length of the control line is along an axis that is substantially orthogonal to the substrate over which the memory array is implemented. Although some examples may refer to DRAM and/or 3D memory, embodiments of the present disclosure may be equally applicable to memory cells implemented other technologies. Thus, in general, memory cells described herein may be implemented as eDRAM cells, spin-transfer torque random-access memory (STTRAM) cells, resistive random-access memory (RRAM) cells, static random-access memory (SRAM), or any other non-volatile memory cells.

In one example, memory cells in a memory array can be read using control lines, e.g., by applying appropriate voltages on one or more control lines, and sensing an electrical output (e.g., sensing the magnitude and/or change in magnitude of a charge, voltage, or current) on a control line. In some examples, the signal-to-noise ratio (SNR) associated with reading from a memory cell in a memory array may be low, which can result in errors in the values read from the memory array. Some types of memory, such as 3D memory, may be especially susceptible to errors due to a low SNR (e.g., due to parasitic capacitance loading a vertical bitline). The signal-to-noise ratio may also be reduced in memory devices operated at a very low temperature. For example, the signal-to-noise ratio may be especially significant at low temperature operation (e.g., due to an increase in the on/off current ratio for the sense transistors).

In accordance with examples described herein, IC devices with a memory array and shared gain elements may have improved signal-to-noise ratio compared to prior memory technologies. In one example, an IC device includes a plurality of memory cells, a control line (such as a bitline or plateline) coupled with the plurality of memory cells, and a transistor (e.g., a transistor that is a shared gain element) with a gate terminal coupled with the control line (and thus coupled with a plurality of memory cells). In one such example, the memory array may be implemented in back end of line (BEOL) layers or a front-end of line (FEOL) layer, and the gain elements may also be in a BEOL layer or FEOL layer. The memory array may include memory cells of any suitable memory technology, and the gain element may include a transistor of any suitable transistor technology. Thus, instead of connecting the control line directly to a sense amplifier for reading the value in a memory cell, in one example, the control line is coupled with the gate of a transistor to increase the voltage being sensed on the control line and improve the signal-to-noise margin. In one example, the transistor thus acts as a gain element that is shared by the plurality of memory cells coupled with the control line.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETS, designations of source and drain are often interchangeable. Therefore, descriptions of some illustrative embodiments of the source and drain regions/contacts provided herein are applicable to embodiments where the designation of source and drain regions/contacts may be reversed. Furthermore, although descriptions of the present disclosure may refer to logic devices or memory cells provided in a given layer, each layer of the IC devices described herein may also include other types of devices besides logic or memory devices described herein. For example, in some embodiments, IC devices with BEOL DRAM cells may also include SRAM memory cells, or any other type of memory cells, in any of the layers.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal. In the context of the present disclosure, the term “above” may refer to being further away from the support structure or the FEOL of an IC device, while the term “below” refers to being closer towards the support structure or the FEOL of the IC device.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

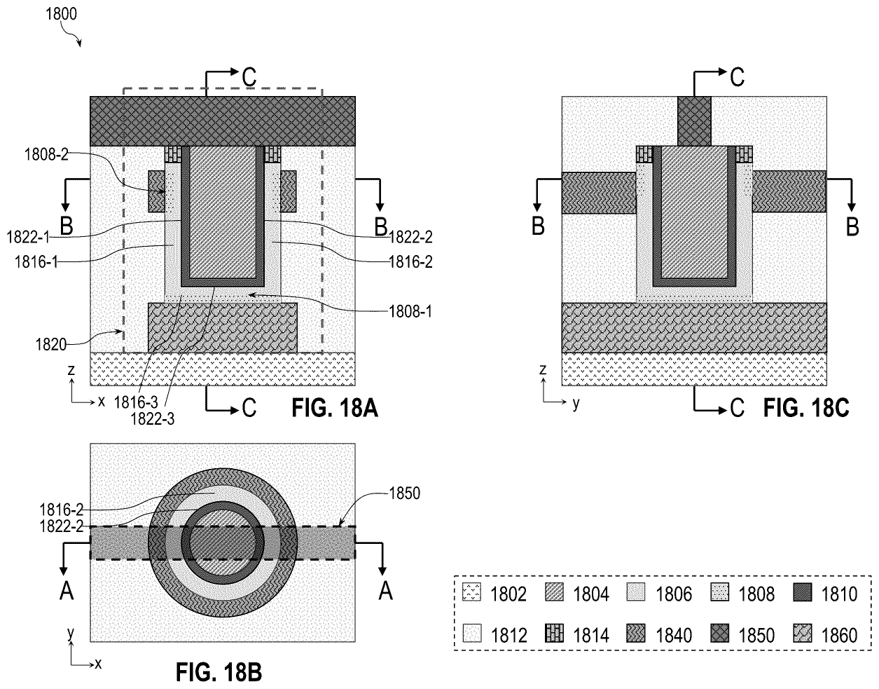

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 18A-18C, such a collection may be referred to herein without the letters, e.g., as “FIG. 18.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with a memory array and shared gain elements as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

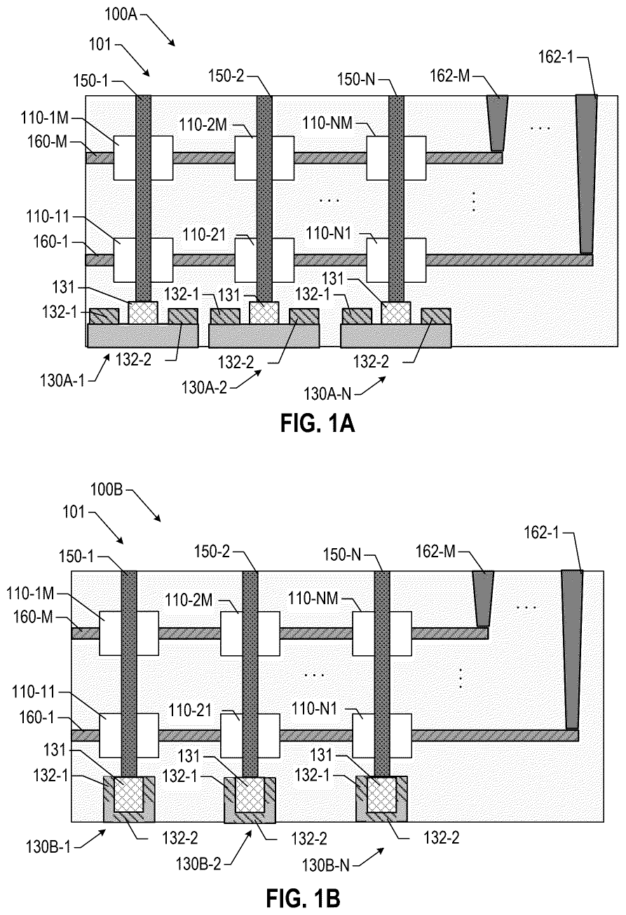

FIGS. 1A-1B illustrate example IC structures including a memory array and shared gain elements, in accordance with embodiments described herein. The example illustrated in FIGS. 1A-1B is an example of a stacked or 3D memory array. The IC structures 100A and 100B of FIGS. 1A-1B each include an array 101 of memory cells 110-11-110-NM (of which memory cells 110-11, 110-1M, 110-21, 110-2M, 110-N1, and 110-NM are depicted) coupled with a first plurality of control lines 150-1-150-N (of which control lines 150-1, 150-2, and 150-N are depicted) and a second plurality of control lines 160-1-160-M (of which control lines 160-1 and 160-M are depicted). Control lines may also be referred to as conductive lines, conductive access lines, or access lines. In the example illustrated in FIGS. 1A and 1B, the IC structures 100A, 100B includes M×N memory cells 110-11-110-MN, N control lines 150-1-150-N (e.g., vertical control lines) extending along an axis substantially orthogonal to a substrate over which the array 101 is disposed, and M control lines 160-1-160-M extending along an axis substantially parallel to the substrate and orthogonal to the control lines 150-1-150-N. The first plurality of control lines 150-1-150-N may be, for example, bitlines or platelines, via which the memory cells 110-11-110-NM may be accessed. In an example in which the control lines 150-1-150-N are bitlines, the second plurality of control lines may be, for example, platelines or wordlines, depending on the memory technology implemented in the array 101. In one example in which the control lines 150-1-150-N are platelines, the second plurality of control lines may be, for example, bitlines. The IC structure includes interconnects 162-1-162-M (of which interconnects 162-1 and 162-M are depicted) coupled with the control lines 160-1-160-M, which couple the control lines 160-1-160-M to other components such as control circuitry (e.g., control line driver circuitry, etc.). In general, N and M may be any integer greater than 1 and may be different from one another, although in some specific embodiments these variables may be of the same value (e.g., the number of control lines 150 may be equal to the number of control lines 160). Although only two types of control lines 150 and 160 are depicted in FIGS. 1A and 1B, in some examples the memory cells 110-11-110-MN are accessible via three control lines (e.g., bitlines, wordlines, and platelines).

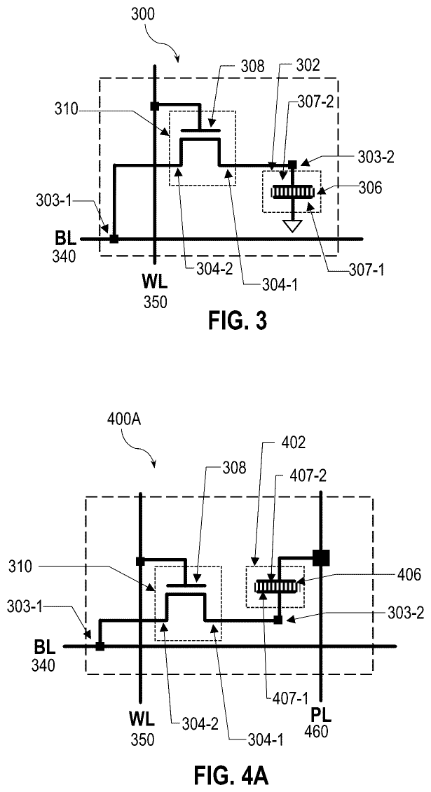

The memory cells 110-11-110-NM may be implemented with a variety of technologies, and typically includes a storage element (e.g., one or more capacitors, a hysteretic element of a capacitor or a transistor, and/or another storage element) and an element controlling access to the memory cell (e.g., an access transistor). For example, a memory cell may include a capacitor for storing a bit value, or a memory state (e.g., logical “1” or “0”) of the cell, and an access transistor for controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). In another example, a memory cell may include one access transistor coupled with a plurality of capacitors (e.g., a “1T-multiple C” memory cell). In another example, the access transistor of a memory cell may include a storage element or hysteretic element without a separate capacitor. FIGS. 3-6, discussed below, illustrate example circuit diagrams of various memory cells. An IC structure including a memory array and shared gain elements as disclosed herein may also, or alternatively, include other memory cell technologies other than those specifically described herein.

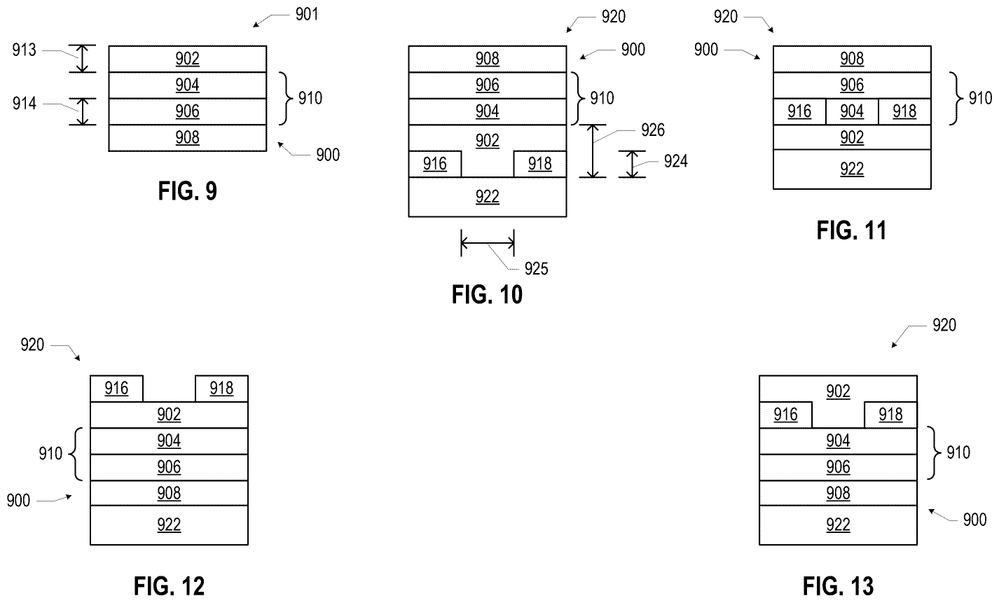

Referring again to FIGS. 1A-1B, the IC structures 100A, 100B include a plurality of gain elements coupled with the control lines 150-1-150-N. For example, the IC structure 100A of FIG. 1A includes a plurality of transistors 130A-1-130A-N, and the IC structure 100B of FIG. 1B includes a plurality of transistors 130B-1-130B-N. The transistors 130A-1-130A-N and 130B-1-130B-N may also be referred to as sense transistors or gain transistors, where a gain element may be or include a sense/gain transistor. The IC structure 100A of FIG. 1A depicts planar transistors as the sense transistors 130A-1-130A-N, and the IC structure 100B depicts vertical transistors as the sense transistors 130B-1-130B-N; however, IC structures including a memory array and shared gain elements may include transistors of any architecture, such as any non-planar or planar architecture. Non-planar transistors such as double-gate transistors, tri-gate transistors, vertical transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors. Examples of transistor architectures are described below with respect to FIGS. 9-15, 16A-16B, 17A-17B, and 18A-18B. An IC structure including a memory array and shared gain elements as disclosed herein may also, or alternatively, include other transistor technologies other than those specifically described herein.

Referring again to FIGS. 1A-1B, each of the transistors 130A-1-130A-N and 130B-1-130B-N include a gate terminal 131 and two S/D terminals 132-1, 132-2. A gate terminal may alternatively be referred to as a gate, gate stack, gate contact, or gate electrode of a transistor, and an S/D terminal may alternatively be referred to as an S/D region, S/D contact, or S/D electrode. In the examples illustrated in FIGS. 1A-1B, instead of coupling directly with a sense amplifier, the control lines 150-1-150-N are coupled with the gate terminal 131 of respective transistors 130A-1-130A-N, 130B-1-130B-N. A gain element is therefore “shared” by the memory cells coupled with the same control line that is coupled with the gate terminal of the gain/sense transistor. Thus, the IC structures 100A, 100B differ from other memory arrays with gain elements in which the gain element is a part of each of the memory cells. In contrast, in one example of an IC device with a memory array and shared gain elements, the gain element is shared by a plurality of memory cells by connecting a common control line (e.g., a control line coupled with the plurality of memory cells) to the gate of the shared gain/sense transistor. Referring again to FIGS. 1A, 1B, in one example, one of the S/D terminals 132-1, 132-2 is coupled with a sense amplifier. Another of the S/D terminals 132-1, 132-2 may be coupled with, e.g., a voltage source or another control line, depending on the implementation. Thus, the IC structures 100A, 100B include transistors 130A-1-130A-N and 130B-1-130B-N (e.g., between the memory cells 110-11-110-NM and sense amplifiers), where the vertical control lines 150-1-150-N are coupled with the gate terminals 131 of the respective transistors 130A-1-130A-N and 130B-1-130B-N. In one example, the charge or voltage sensed on the control lines 150-1-150-N is amplified by the transistors 130A-1-130A-N and 130B-1-130B-N, which enables a higher amplitude voltage to be sensed by the sense amplifier, improving the signal-to-noise ratio.

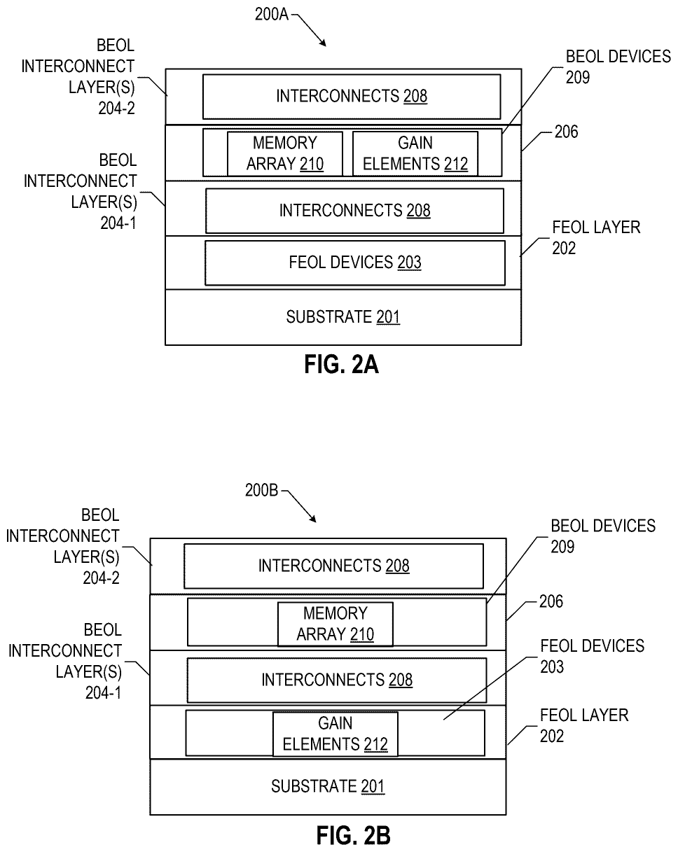

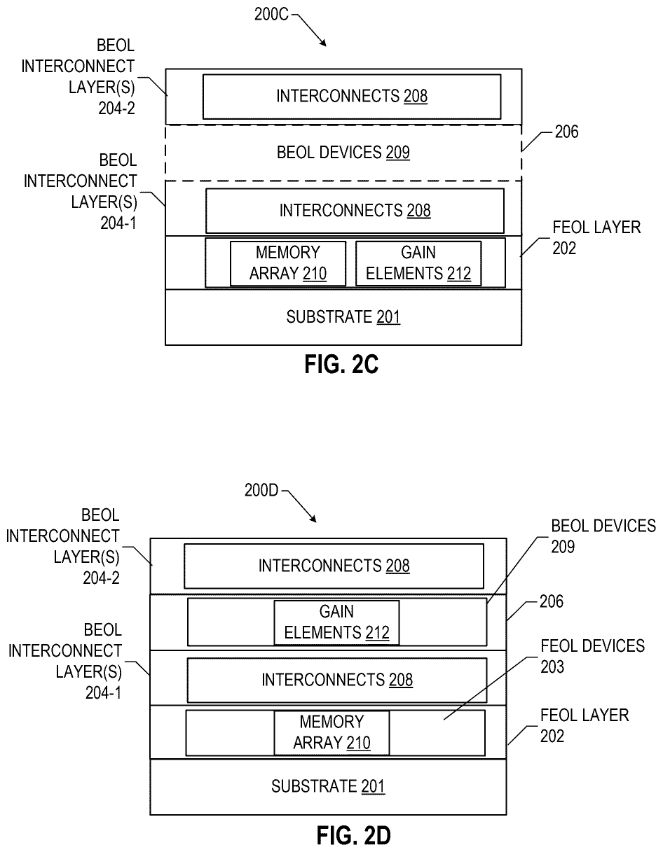

In some examples, a memory array may be implemented in BEOL layer(s) or FEOL layer(s), and the gain elements may similarly be implemented in BEOL layer(s) or FEOL(s). FEOL typically refers to the first stage of semiconductor manufacturing in which individual semiconductor devices components (e.g., transistor, capacitors, resistors, etc.) can be patterned in a wafer. BEOL typically refers to a second stage of semiconductor manufacturing in which interconnect structures such as conductive lines and conductive vias, separated as needed by an insulator material, can be formed to connect components. FIGS. 2A-2D illustrate block diagrams of example IC structures including a memory array and shared gain elements.

The IC structures 200A-200D include one or more FEOL layers, depicted as the FEOL layer 202, and one or more BEOL layers over the FEOL layer(s), depicted in FIGS. 2A-2D as BEOL interconnect layers 204-1, 204-2 and a BEOL device layer 206. The FEOL layer 202 may include a plurality of FEOL devices 203, e.g., frontend transistors such as FinFETs, nanowire transistors, nanoribbon transistors, memory cells, etc., in a device region over a support structure or substrate 201. Examples of a substrate are discussed below with respect to FIG. 10. The BEOL device layer 206 includes a plurality of BEOL devices 209, e.g., backend transistors such as FinFETs, nanowire transistors, nanoribbon transistors, memory cells, etc. Transistors implemented in the FEOL layer 202 and/or in the BEOL device layer 206 may be logic transistors, sense transistors, or access transistors for memory cells. The BEOL interconnect layers 204-1, 204-2 may include a plurality of backend interconnects electrically coupled to (e.g., in electrically conductive contact with at least portions of) one or more of the plurality of FEOL devices 203 of the FEOL layer 202 and/or one or more of the plurality of backend devices 209 of the BEOL device layer 206.

Various BEOL interconnect layers 204-1, 204-2 may be/include one or more metal layers of a metallization stack of the IC device. Various metal layers of the BEOL interconnect layers 204-1, 204-2 may be used to interconnect the various inputs and outputs of the devices of the FEOL layer 202 and/or of the BEOL device layer 206. In one example, each of the BEOL interconnect layers 204-1, 204-2 include interconnects 208, which may include one or more vias and lines/traces or trenches. The trenches of a metal layer are configured for transferring signals and power along electrically conductive (e.g., metal) lines extending in a plane substantially parallel with the substate 201, while the vias of a metal layer are configured for transferring signals and power through electrically conductive vias extending through layers in a plane substantially orthogonal to the substrate 201, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 204-1, 204-2 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD).

FIG. 2A illustrates an example IC structure 200A that includes a memory array 210 and shared gain elements for the memory array in a BEOL layer 206. FIG. 2B illustrates an example IC structure 200B that includes a memory array 210 in a BEOL layer 206, and shared gain elements 212 for the memory array 210 in a FEOL layer 202. FIG. 2C illustrates an example IC structure 200C that includes a memory array 210 and shared gain elements 212 in a FEOL layer 202 (and which may or may not include a BEOL layer 206 with backend logic and/or memory devices, as indicated with the dashed contour). FIG. 2D illustrates an example IC structure 200D that includes a memory array 210 in a FEOL layer 202 and shared gain elements in a BEOL layer 206. Thus, the memory array and gain elements may be implemented in either the front end or back end. In some examples, memory arrays implemented in the backend may include stacked memory arrays (e.g., 3D memory arrays). In some examples, implementing the gain elements 212 in a FEOL layer for a backend memory array may enable higher quality and more robust gain elements.

FIGS. 3-6 illustrate example circuit diagrams for various memory cell architectures that may be implemented in a memory array with shared gain elements.

FIG. 3 is a circuit of a one access transistor and one capacitor (1T-1C) DRAM memory cell, according to some embodiments of the present disclosure. FIG. 3 illustrates one example of how an access transistor 310 and a capacitor 302 may be used to form a 1T-1C memory cell. In particular, the memory cell 300 illustrates the S/D regions 304-1, 304-2 and the gate terminal 308 of the transistor 310, and further illustrates the capacitor 302 coupled to one of the S/D regions 304-1, 304-2 of the transistor 310. In various embodiments, the transistor 310 may be any FET, e.g., the transistor 310 may be either an N-type metal-oxide-semiconductor (NMOS) transistor or a P-type metal-oxide-semiconductor (PMOS) transistor. The capacitor 302 may be any suitable capacitor, e.g., a metal-insulator-metal (MIM) capacitor for storing a bit value, or a memory state of the memory cell 300, and the transistor 310 may then function as an access transistor controlling access to the memory cell 300 (e.g., access to write information to the cell or access to read information from the cell. The capacitor 302 is shown to include a first capacitor electrode 307-1 and a second capacitor electrode 307-2, and an insulator material (i.e., the capacitor insulator 306) between the first and second capacitor electrodes 307-1, 307-2.

The memory cell 300 further illustrates a bitline 340 (labeled in FIG. 3 and some other drawings as “BL”) and a wordline 350 (labeled in FIG. 3 and some other drawings as “WL”). In one example, the bitline 340 may be an example of the control line coupled with the gate of the sense/gain transistor, such as the control lines 150-1-150-N of FIGS. 1A and 1B. Each of the bitline 340 and the wordline 350, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, aluminum, tantalum nitride, tungsten, doped silicon, doped germanium, or alloys and mixtures of any of these. In some embodiments, such electrically conductive materials may include one or more electrically conductive alloys oxides or carbides of one or more metals.

As shown in FIG. 3, in the 1T-1C memory cell 300, the gate terminal (e.g., the gate terminal 308) of the access transistor 310 is coupled to the wordline 350, the first S/D terminal (e.g., the first S/D region 304-1) is coupled to the capacitor 302, and the second S/D terminal (e.g., the second S/D region 304-2) is coupled to the bitline 340. In particular, the first S/D region 304-1 is coupled to the first capacitor electrode 307-1. In the example illustrated in FIG. 3, the second capacitor electrode 307-2 is coupled with ground. As is known in the art, the wordlines and bitlines may be used together to read and program the capacitor 302. For example, by turning on the transistor 310, charge sharing occurs, bringing the node 303-1 on the bitline 340 and the node 303-2 between the transistor 310 and the capacitor 302 to the same voltage. Typically, there is a relatively small sense margin, which can lead to errors in the resulting read value. However, including a second shared gain transistor between the bitline 340 and a sense amp can enable amplifying the voltage sensed by the sense amp. In one example, the bitline 340, and thus the S/D region 304-2 of the transistor 310, may be coupled with the gate terminal of a second transistor (e.g., a gain/sense transistor such as one of the transistors 130A-1-130A-N and 130B-1-130B-N of FIGS. 1A, 1B). Thus, in one example, by coupling the bitline 340 to the gate of another transistor instead of directly to a sense amplifier, the value (e.g., voltage or current) provided to the sense amplifier may be significantly increased, improving the signal-to-noise ratio.

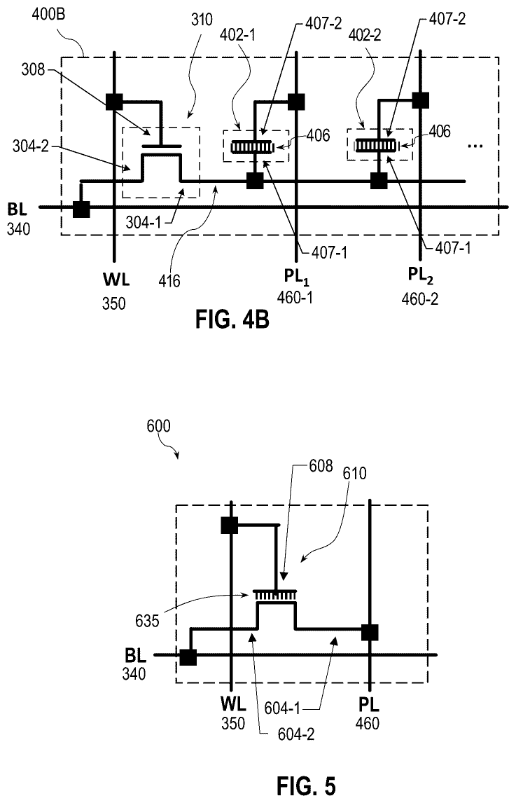

FIGS. 4A-4B are circuit diagrams of example memory cells that include an access transistor and one or more capacitors, where the memory cells are accessible with a plateline, bitline, and wordline. FIG. 4A is a circuit diagram of a 1T-1C memory cell 400A, according to one embodiment of the present disclosure. FIG. 4B illustrates an example of a memory unit 400B that includes an access transistor and multiple capacitors coupled with different platelines, according to some embodiments of the present disclosure.

FIG. 4A illustrates another example of how an access transistor 310 and a capacitor 302 may be used to form a 1T-1C memory cell. In particular, the memory cell 300 illustrates an example of a memory cell that is further accessed with a plateline 460. In one example, the memory cell 400A is an example of a ferroelectric memory cell (e.g., an FEDRAM memory cell). Like the memory cell 300 of FIG. 3, the memory cell 400A of FIG. 4A includes an access transistor 310 and a capacitor 402. The access transistor 310 may be implemented in accordance with any examples described herein, and may be similar to or the same as the access transistor 310 of FIG. 3. The capacitor 402 may be any suitable capacitor for storing a bit value or a memory state of the memory cell 400A, and the transistor 310 may then function as an access transistor controlling access to the memory cell 400A.

The capacitor 402 is shown to include a first capacitor electrode 407-1 and a second capacitor electrode 407-2, and an insulator material (e.g., the capacitor insulator 406) between the first and second capacitor electrodes 407-1, 407-2. In some embodiments, instead of, or in addition to, a regular dielectric material used in conventional dielectric (i.e., not hysteretic) capacitors, the capacitor insulator 406 of the capacitor may include a hysteretic material or a hysteretic arrangement, which, together, may be referred to as a “hysteretic element.” In such embodiments, the capacitor 402 may be described as “hysteretic capacitor.”

In some embodiments, the hysteretic element of the capacitor insulator 406 may be provided as a layer of a ferroelectric (FE) or an antiferroelectric (AFE) material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic elements of the capacitor insulators 306 and are within the scope of the present disclosure.

In other embodiments, the hysteretic element of the capacitor insulator 306 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell. In some embodiments of the hysteretic element of the capacitor insulator 406 being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

The memory cell 400A further illustrates a bitline 340, a wordline 350, and a plateline 460 (labeled in FIG. 4A and some other drawings as “PL”). The plateline 460 may include a suitable conductive material, such as those described above with respect to the wordline 350 and the bitline 340. In one example, the bitline 340 may be an example of the control line coupled with the gate of the sense/gain transistor (e.g., one of the control lines 150-1-150-N of FIGS. 1A and 1B). In another example, the plateline 460 may be an example of the control line coupled with the gate of the sense/gain transistor.

As shown in FIG. 4A, in the 1T-1C memory cell 400A, the gate terminal (e.g., the gate terminal 308) of the access transistor 310 is coupled to the wordline 350, the first S/D terminal (e.g., the first S/D region 304-1) is coupled to the capacitor 402, and the second S/D terminal (e.g., the second S/D region 304-2) is coupled to the bitline 340. In particular, the first S/D region 304-1 is coupled to the first capacitor electrode 407-1, while the second capacitor electrode 407-2 is coupled to the plateline 460. As is known in the art, the wordlines, bitlines, and platelines may be used together to read and program the capacitor 302. For example, by turning on the transistor 310 (e.g., by applying an appropriate voltage to the gate terminal 308 of the transistor 310) and applying an appropriate voltage to the plateline, the value stored in the capacitor 402 may be sensed (e.g., on the bitline 340). In one such example, the bitline 340, and thus the S/D region 304-2 of the transistor 310, may be coupled with the gate terminal of a second transistor (e.g., a sense transistor such as one of the transistors 130A-1-130A-N and 130B-1-130B-N), which may improve the signal-to-noise ratio.

Thus, FIG. 4A illustrates a circuit diagram of another example 1T-1C memory cell that may be included in a memory array with shared gain elements in accordance with examples described herein.

As shown in FIG. 4B, the circuit diagram of the memory unit 400B includes the access transistor 310, described above with respect to FIGS. 3-4A. Like in FIG. 4A, the gate terminal 308 of the access transistor 310 of FIG. 4B may be coupled to a wordline 350 and one of the source or drain regions (e.g., the S/D region 304-2) of the access transistor 310 may be coupled to a bitline 340. The other one of the source or drain regions (e.g., the S/D region 304-1) of the access transistor 310 may be coupled, via an intermediate node 416, to a first capacitor electrode 407-1 of each of the N capacitors of the memory unit 400B (only two such capacitors 402-1, 402-2 are shown in FIG. 4B, but the possibility of additional capacitors is illustrated in FIG. 4B with three dots to the right side of the capacitor 402-2). As further shown in FIG. 4B, second capacitor electrodes 407-2 of different ones of the capacitors 402-1, 402-2 of the memory unit 400B are coupled to respective (i.e., different) platelines 460-1, 460-2. FIG. 4B further illustrates that each of the capacitors 402-1, 402-2 includes a capacitor insulator 406 between the first and second capacitor electrodes, discussed above with respect to FIG. 4A.

In one example, the memory unit 400B includes multiple memory cells, each memory cell including a different one of the capacitors 402-1, 402-2 as a storage element that is accessible with the access transistor 310. For example, a first memory cell of the memory unit 400B includes the capacitor 402-1 and is accessible with the bitline 340, the wordline 350, and the first plateline 460-1, and a second memory cell of the memory unit 400B includes the capacitor 402-2 and is accessible with the bitline 340, the wordline 350, and the second plateline 460-2. In one such example, each of the capacitors in the memory array may be addressable with a unique combination of control lines, e.g., each capacitor may be associated with a particular combination of WL, PL, and BL. In one example, the bitline 340 or platelines 460-1, 460-2 may be implemented as the control lines that is coupled with the gate of a shared gain element. For example, the bitline 340 or the platelines 460-1, 460-2 may be coupled with the gate of a gain/sense transistor, such as the transistors 130A-1-130A-N and 130B-1-130B-N of FIGS. 1A and 1B.

FIG. 5 is a circuit diagram of another memory cell 600 that may be implemented with a single transistor, according to some embodiments of the present disclosure. As shown in FIG. 5, the transistor 610 has a gate terminal 608, a first S/D terminal 604-1, and a second S/D terminal 604-2. A bitline 340 and a plateline 460 are coupled to different S/D terminals of the transistor 610. In some examples, the transistor 610 may be different from conventional logic transistors in that, instead of or in addition to a gate dielectric material that may be included in the gate, the transistor 610 further includes a hysteretic material or a hysteretic arrangement, which, together, may be referred to as a “hysteretic element 635” (schematically illustrated in FIG. 5 as short parallel vertical lines integrated with the notation of the gate of the transistor 610). In this manner, the hysteretic element 635 (e.g., storage or memory element) of the memory cell 600 is integrated into the gate of the transistor 610 and the transistor 610 may be described as a “hysteretic transistor.” The hysteretic element 635 integrated in the gate of the transistor 610, and may have a thickness that may, in some embodiments, be between about 0.5 nanometers and 10 nanometers, including all values and ranges therein (e.g., between about 1 and 8 nanometers, or between about 0.5 and 5 nanometers).

In some embodiments, the hysteretic element 635 may be provided as a layer of an FE or an AFE material, and may have properties similar to those described above with respect to the insulator material (e.g., the capacitor insulator 406) of the hysteretic capacitor 402 of FIG. 4A. Together, the bitline 340, the wordline 350, and the plateline 460 may be used to read and program the bit state of the memory cell 600 by, respectively, sensing and setting the polarization of the memory material (e.g., polarization of the hysteretic element 635). In some examples, the bitline 340 or the plateline 460 may be an example of a control line which may be coupled with the gate of a shared gain/sense transistor.

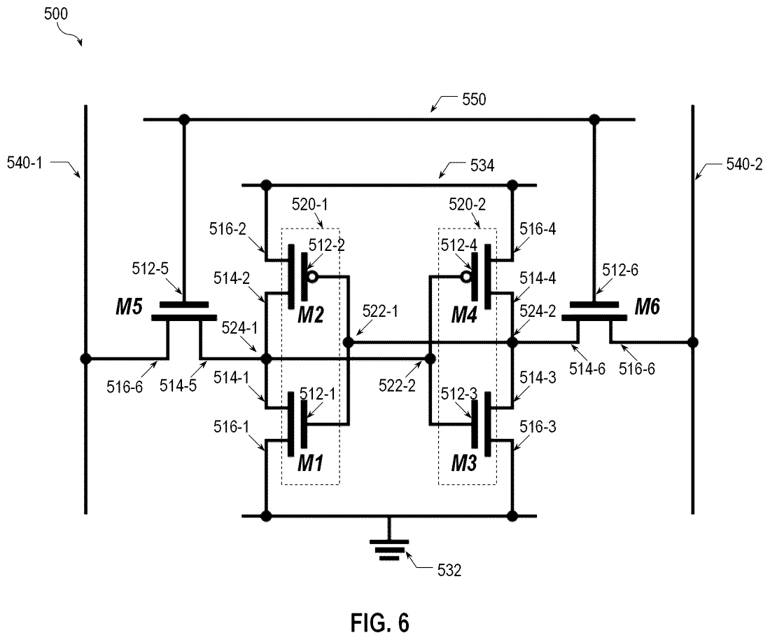

FIG. 6 is circuit diagram of an example 6-transistor (6T) memory cell 500 that may be an SRAM cell used in an SRAM array, according to some embodiments of the present disclosure. The SRAM cell 500 includes transistors M1-M4 for storing a bit value or a memory state (e.g., logic “1” or “0”) of the cell, and two access transistors, M5 and M6, for controlling access to the cell (e.g., access to write information to the cell or access to read information from the cell 500). Each of the transistors M1-M6 may have any transistor architecture (e.g., planar or non-planar, FinFET, nanoribbon/nanowire, etc.).

In the SRAM cell 500, each bit may be stored on four transistors (M1, M2, M3, M4) that form two cross-coupled inverters 520, each having an input 522 and an output 524. The first inverter 520-1 may be formed by an NMOS transistor M1 and a PMOS transistor M2, while the second inverter 520-2 may be formed by an NMOS transistor M3 and a PMOS transistor M4. As shown in FIG. 6, the gate stack 512-1 of the transistor M1 may be coupled to the gate stack 512-2 of the transistor M2, and both of these gate stacks may be coupled to the input 522-1 of the first inverter 520-1. On the other hand, the first S/D region 514-1 of the transistor M1 may be coupled to the first S/D region 514-2 of the transistor M2, and both of these first S/D regions 514-1 and 514-2 may be coupled to the output 524-1 of the first inverter 520-1. Similarly, for the second inverter 520-2, the gate stack 512-3 of the transistor M3 may be coupled to the gate stack 512-4 of the transistor M4, and both of these gate stacks may be coupled to the input 522-2 of the second inverter 520-2, while the first S/D region 514-3 of the transistor M3 may be coupled to the first S/D region 514-4 of the transistor M4, and both of these first S/D regions 514-3 and 514-4 may be coupled to the output 524-2 of the second inverter 520-2. As also shown in FIG. 6, when the transistors M1 and M3 are NMOS transistors and when the transistors M2 and M4 are PMOS transistors as illustrated in FIG. 6, the second S/D regions 516-1 and 516-3 of the transistors M1 and M3 may be coupled to a ground voltage 532, while the second S/D regions 516-2 and 516-4 of the transistors M2 and M4 may be coupled to a supply voltage 534, e.g., VDD. In the embodiments of the SRAM cell 500 where the NMOS transistors shown in FIG. 6 are replaced with PMOS transistors and vice versa, the designation of the ground voltage 532 and the supply voltage 534 would be reversed as well, all of which embodiments being within the scope of the present disclosure.

The four transistors M1-M4 in such configuration form a stable storage cell for storing a bit value of 0 or 1. As further shown in FIG. 6, two additional access transistors, M5 and M6, may serve to control the access to the storage cell of the transistors M1-M4 during read and write operations. As shown in FIG. 6, the first S/D region 514-5 of the access transistor M5 may be coupled to the output 524-1 of the first inverter 520-1. Phrased differently, the first S/D region 514-5 of the access transistor M5 may be coupled to each of the first S/D region 514-1 of the transistor M1 and the first S/D region 514-2 of the transistor M2. The second S/D region 516-5 of the access transistor M5 may be coupled to a first BL 540-1. Thus, each of the first S/D region 514-1 of the transistor M1 and the first S/D region 514-2 of the transistor M2 may be coupled to the first BL 540-1 (e.g., via the access transistor M5). The gate 512-5 of the access transistor M5 may be coupled to a WL 550.

As further shown in FIG. 6, the first S/D region 514-6 of the access transistor M6 may be coupled to the output 524-2 of the second inverter 520-2. Phrased differently, the first S/D region 514-6 of the access transistor M6 may be coupled to each of the first S/D region 514-3 of the transistor M3 and the first S/D region 514-4 of the transistor M4. The second S/D region 516-6 of the access transistor M6 may be coupled to a second BL 540-2. Thus, each of the first S/D region 514-3 of the transistor M3 and the first S/D region 514-4 of the transistor M4 may be coupled to the second BL 540-2 (e.g., via the access transistor M6). The gate 512-6 of the access transistor M6 may be coupled to the WL 550. Thus, the gates 512-5 and 512-6 of both of the access transistors M5 and M6 may be coupled to a single, shared, WL, the WL 550.

As also shown in FIG. 6, the input 522-1 of the first inverter 520-1 may be coupled to the first S/D region 514-6 of the access transistor M6, while the input 522-2 of the second inverter 520-2 may be coupled to the first S/D region 514-5 of the access transistor M5. In other words, each of the gate stack 512-1 of the transistor M1 and the gate stack 512-2 of the transistor M2 may be coupled to the first S/D region 514-6 of the access transistor M6, while each of the gate stack 512-3 of the transistor M3 and the gate stack 512-4 of the transistor M4 may be coupled to the first S/D region 514-5 of the access transistor M5. Phrased differently, each of the gate stack 512-1 of the transistor M1 and the gate stack 512-2 of the transistor M2 may be coupled to the second BL 540-2 (e.g., via the access transistor M6), while each of the gate stack 512-3 of the transistor M3 and the gate stack 512-4 of the transistor M4 may be coupled to the first BL 540-1 (e.g., via the access transistor M5).

The WL 550 and the first and second BLs 540 may be used together to read and program (i.e., write to) the SRAM cell 500. In particular, access to the cell may be enabled by the WL 550 which controls the two access transistors M5 and M6 which, in turn, control whether the cell 500 should be connected to the BLs 540-1 and 540-2. During operation of the SRAM cell 500, a signal on the first BL 540-1 may be complementary to a signal on the second BL 540-2. The two BLs 540 may be used to transfer data for both read and write operations. In other embodiments of the SRAM cell 500, only a single BL 540 may be used, instead of two bitlines 540-1 and 540-2, although having one signal BL and one inverse, such as the two BLs 540, may help improve noise margins.

During read accesses, the BLs 540 are actively driven high and low by the inverters 520 in the SRAM cell 500. This may improve SRAM bandwidth compared to DRAM. The symmetric structure of the SRAMs cell 500 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the WL 550 and the BLs 540, as well as intermediate elements coupling these lines to various terminals described herein, may be formed of any suitable electrically conductive material, such as those discussed above. In one example, the BLs 540 may be an example of control lines coupled with shared gain elements.

Thus, FIGS. 3-6 illustrate circuit diagrams of example memory cells which may be implemented in a memory array with shared gain elements.

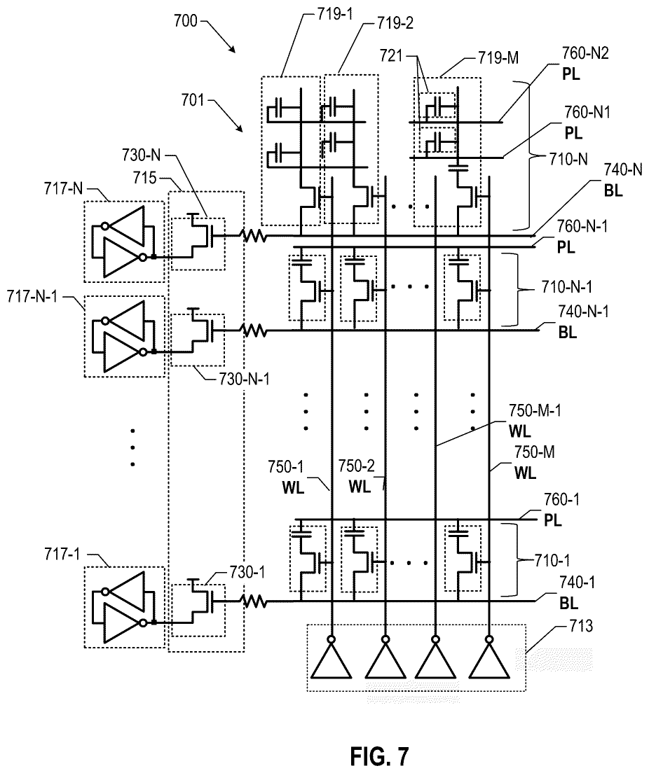

FIG. 7 illustrates an example circuit diagram of a memory array with shared gain elements. In one example, the circuit diagram 700 depicts an example diagram of the IC structures 100A, 100B of FIGS. 1A and 1B. In the example illustrated in FIG. 7, the circuit diagram 700 includes a memory array 701 coupled with wordline driver circuitry 713 and gain elements 730-1-730-N, where the gain elements 730-1-730-N are coupled with sense or sensing circuitry 715 and respective bitlines 740-1-740-N. The sensing circuitry 715 includes a plurality of sense amplifiers 717-1-717-N (of which sense amplifiers 717-1, 717-N−1, and 717-N are depicted) for sensing values on the respective bitlines 740-1-740-N, as output by the gain elements 730-1-730-N. In the example illustrated in FIG. 7, the memory array 701 includes a plurality of memory cells coupled with each of the bitlines 740-1-740-N. For example, the plurality of memory cells 710-1 is coupled with the bitline 740-1, where an individual memory cell of the plurality of memory cells 710-1 is indicated with the dotted contour. The plurality of memory cells 710-N−1 (where N−1 represents N minus 1) is coupled with the bitline 740-N−1, and the plurality of memory cells 710-N is coupled with the bitline 740-N. The circuit diagram 700 depicts two types of memory cells; specifically, the pluralities of memory cells 710-1, 710-N−1 are depicted as 1T-1C memory cells (e.g., such as the memory cell 400A of FIG. 4A), and the plurality of memory cells 710-N are depicted as 1T-many C memory cells (e.g., such as the memory unit 400B of FIG. 4B). Thus, the plurality of memory cells 710-N includes a plurality of memory units 719-1-719-M (of which memory units 719-1, 719-2, and 719-M are depicted), where each of the memory units 719-1-719-M includes an access transistor and a plurality of capacitors 721 (e.g., where an individual capacitor of the memory unit may be considered a memory cell).

In the example illustrated in FIG. 7, the memory cells of the array 701 are accessible with a plurality of wordlines 750-1-750-M (of which wordlines 750-1, 750-2, 750-M−1, and 750-M are depicted), a plurality of bitlines 740-1-740-N (of which bitlines 740-1, 740-N−1, and 740-N are depicted), and a plurality of platelines 760-1-760-N−1, and 760-N1-7600-N2 (of which platelines 760-1, 760-N−1, 760-N1, and 760-N2 are depicted). Thus, in one example, the array 701 includes memory cells such as ferroelectric or antiferroelectric memory cells, or another memory cell architecture in which wordlines, bitlines, and platelines may be used to access the memory cells of the array. In the example illustrated in FIG. 7, each of the bitlines is coupled with the gate of a corresponding gain/sense transistor. For example, the bitline 740-1 is coupled with the gate terminal of the transistor 730-1 (e.g., via a resistive element as depicted in the circuit diagram 700). Similarly, the bitline 740-N is coupled with the gate terminal of the transistor 730-N. As discussed above, the shared gain elements (e.g., the transistors 730-1-730-N) can increase the magnitude of the signals sensed by the sense amplifiers 717-1-717-N on the corresponding bitlines 740-1-740-N.

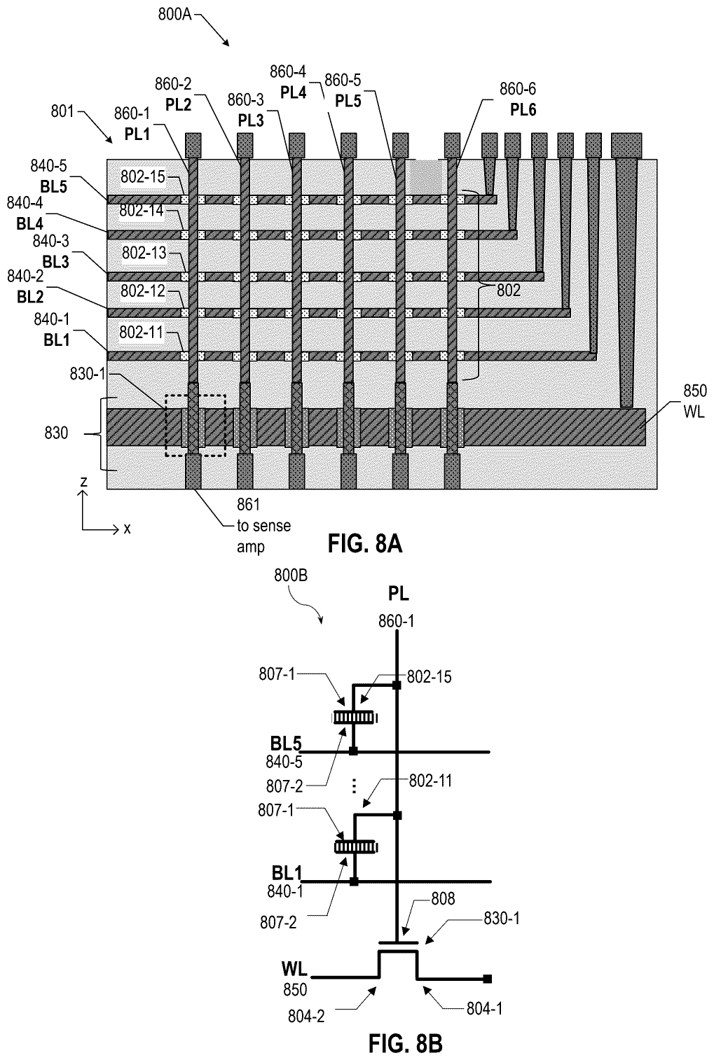

FIG. 8A illustrates another example cross-sectional view of an IC structure 800A including a memory array 801 and shared gain elements (e.g. transistors 830). The example illustrated in FIG. 8A depicts an array of capacitors 802 accessible with a plurality of vertical platelines 860-1-860-6, a plurality of bitlines 840-1-840-5, and a wordline 850. In the example illustrated in FIG. 8A, the memory array 801 is a 3D array in which capacitors 802 are disposed in layers that are stacked over one another. The capacitors 802-11, 802-12, 802-13, 802-14, and 802-15 are labeled in FIG. 8A for illustrative purposes; however, not all of the capacitors 802 are individually labeled in order to not obscure the clarity of the drawing. In the example illustrated in FIG. 8A, the platelines 860-1-860-6 are substantially orthogonal to a substate over which the array 801 is disposed. In the example illustrated in FIG. 8A, the bitlines 840-1-840-5 and the wordline 850 are substantially parallel to one another, and substantially orthogonal to the platelines 860-1-860-6. In another example, the IC structure 800A may include vertical bitlines instead of vertical platelines (e.g., the bitlines may run substantially orthogonal to the substrate, and the platelines may run substantially parallel to the substrate).

In the example illustrated in FIG. 8A, a plurality of the capacitors 802 are coupled with one of the platelines 860-1-860-6, and each of the capacitors coupled with a given plateline is coupled with a different one of the bitlines 840-1-840-5. In one example, the value stored in an individual capacitor may be read (e.g., sensed) via a corresponding plateline (e.g., by applying appropriate voltages to the corresponding wordline, bitline, and/or plateline). For example, the value stored in the capacitor 802-11 may be sensed using the bitline 840-1, the plateline 860-1, and the wordline 850. In the example illustrated in FIG. 8A, each of the plurality of platelines 860-1-860-6 are coupled with the gate of a corresponding shared gain/sense transistor (e.g., one of the transistors 830), and each of the transistors 830 may be coupled with a sense amplifier. The transistors 830 are depicted as vertical transistors (e.g., similar to the transistors 130B-1-130B-N of FIG. 1B). Thus, in one example, the platelines are coupled with the gates of the gain transistors 830 (i.e., each of the platelines is coupled with the gate of a different one of the gain transistors 830), a wordline is coupled with a first of the S/D regions of the gain transistors 830, and a second of the S/D regions of the gain transistors 830 is coupled with a sense amplifier (e.g., as shown by an electrode 861).

FIG. 8B is an example circuit diagram 800B of a portion of the IC structure 800A depicting the capacitors 802-11, 802-15, the plateline 860-1, the bitlines 840-1, 840-5, and the transistor 830-1. The capacitors 802-11, 802-15 may be examples of the capacitors 402 of FIGS. 4A and 4B. As can be seen in the circuit diagram 800B, each of the capacitors 802-11, 802-15 includes a first capacitor electrode 807-1 and a second capacitor electrode 807-2. In the example illustrated in FIG. 8B, the first capacitor electrodes 807-1 are coupled with the plateline 860-1, and the second capacitor electrodes 807-2 are coupled with respective bitlines (e.g., the capacitor electrode 807-2 of the capacitor 802-11 is coupled with the bitline 840-1, and the capacitor electrode 807-2 of the capacitor 802-15 is coupled with the bitline 840-5).

The transistor 830-1 includes a gate terminal 808, and two S/D terminals 804-1, 804-2, where the gate terminal 808 is coupled with the plateline 860-1. In the example illustrated in FIG. 8B, one of the S/D terminals 804-2 is coupled with the wordline 850, and another of the S/D terminals 804-1 may be coupled with a sense amplifier. As discussed above, the sense transistor 830-1 may act to amplify the value sensed on the vertical platelines 860-1, which may improve the signal-to-noise ratio for the memory array.

FIGS. 9-15, 16A-16B, 17A-17B, and 18A-18C illustrate examples of IC structures including different transistor architectures that may be implemented as sense/gain transistors or access transistors in IC structures including memory arrays and shared gain elements, as described herein.

FIG. 9 is a cross-sectional side view of a transistor gate-channel arrangement 901 including a channel material 902 and a transistor gate stack 900 (also referred to as a “gate stack 900” herein), in accordance with various embodiments. FIGS. 9-15, 16A-16B, and 17A-17B illustrate transistors of different architectures that may be implemented as sense/gain transistors or access transistors in IC structures including memory arrays and shared gain elements. N-type and P-type transistors of IC structures with a memory array and shared gain elements as described herein may be transistors of any of the architectures described with reference to FIGS. 9-15, 16A-16B, and 17A-17B.

Turning to the details of FIG. 9, as shown, the transistor gate stack 900 may include a gate electrode material 908, and a gate dielectric stack 910 disposed between the gate electrode material 908 and the channel material 902.

The channel material 902 may be composed of semiconductor material systems including, for example, N-type or P-type materials systems. In some embodiments, the channel material 902 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 902 may include a combination of semiconductor materials. In some embodiments, the channel material 902 may include a monocrystalline semiconductor, such as silicon (Si) or germanium (Ge). In some embodiments, the channel material 902 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (e.g., for the embodiments where a transistor 920 of any of FIGS. 9-15, 16A-16B, and 17A-17B is an NMOS transistor), the channel material 902 may include a III-V material having a relatively high electron mobility, such as, but not limited to InGaAs, InP, InSb, and InAs. For some such embodiments, the channel material 902 may be a ternary III—V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (e.g., for the embodiments where a transistor 920 of any of FIGS. 9-15, 16A-16B, and 17A-17B is a PMOS transistor), the channel material 902 may advantageously be a group IV material having a high hole mobility, such as, but not limited to Ge or a Ge-rich SiGe alloy. For some example embodiments, the channel material 902 may have a Ge content between 0.6 and 0.9, and advantageously may be at least 0.7.

In some embodiments, the channel material 902 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if a transistor is a thin-film transistor (TFT), the channel material 902 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. The channel material 902 may have a thickness 913. In some embodiments, the thickness 913 may be between about 5 and 75 nanometers, including all values and ranges therein, e.g., between about 5 and 30 nanometers.

The gate electrode material 908 may include at least one P-type work function metal or N-type work function metal, depending on whether the transistor gate stack 900 is to be included in a P-type transistor or an N-type transistor. For a P-type transistor, metals that may be used for the gate electrode material 908 may include, but are not limited to, ruthenium, palladium, platinum, cobalt, nickel, and conductive metal oxides (e.g., ruthenium oxide). For an N-type transistor, metals that may be used for the gate electrode material 908 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 908 may include a stack of two or more metal layers, where one or more metal layers are work function metal layers and at least one metal layer is a fill metal layer. Further metal layers may be included for other purposes, such as to act as a barrier layer.

The gate dielectric stack 910 may include a high-k dielectric 906. In some examples, the gate dielectric stack 910 may include one or more other materials such as the insulator material 904. In other examples, the gate dielectric stack 910 may have a single insulator material (e.g., the high-k dielectric 906) between the gate electrode material 908 and the channel material 902.

The high-k dielectric 906 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 906 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric 906 during manufacture of the gate stack 900 to improve the quality of the high-k dielectric 906. The high-k dielectric 906 may have a thickness 914. In some embodiments, the thickness 914 may be between 0.5 nanometers and 3 nanometers (e.g., between 1 and 3 nanometers, or between 1 and 2 nanometers).

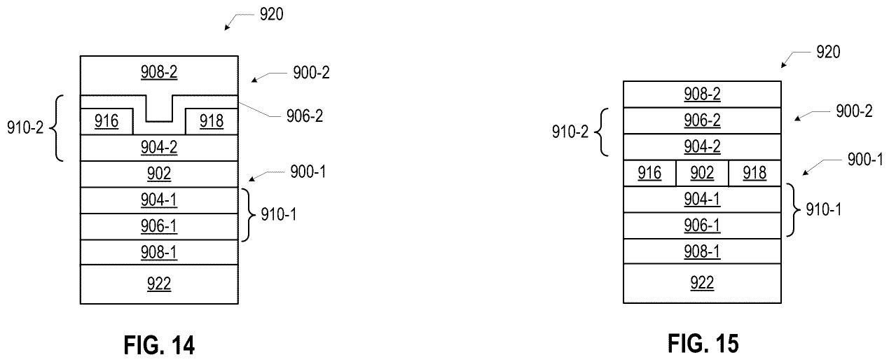

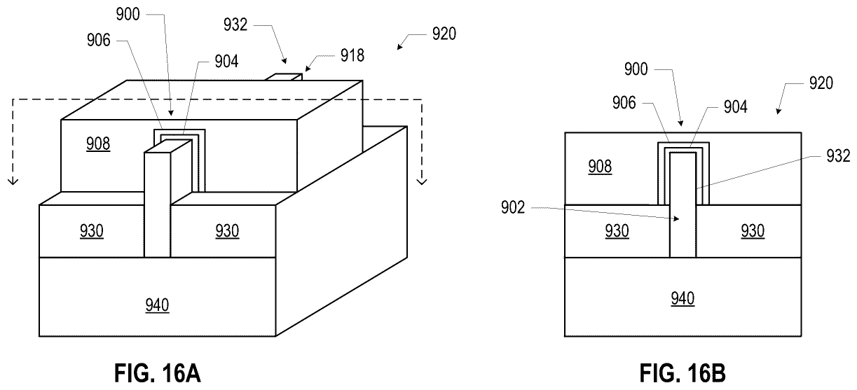

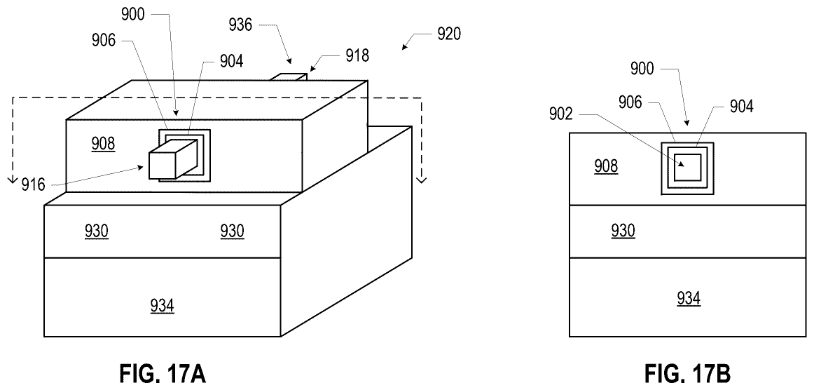

The transistor gate stack 900 may be included in any suitable transistor structure. For example, FIGS. 10-13 are cross-sectional side views of example single-gate transistors 920, FIGS. 14-15 are cross-sectional side views of example double-gate transistors 920, FIGS. 16A and 16B are perspective and cross-sectional side views, respectively, of an example tri-gate transistor 920, and FIGS. 17A and 17B are perspective and cross-sectional side views, respectively, of an example all-around gate transistor 920, any of which may be implemented as sense/gain transistors or access transistors in IC structures including memory arrays and shared gain elements, in accordance with various embodiments. The transistors 920 illustrated in FIGS. 9-15, 16A-16B, and 17A-17B do not represent an exhaustive set of transistor structures that may be implemented as sense/gain transistors or access transistors in IC structures including memory arrays and shared gain elements, but that may provide examples of such structures. Although particular arrangements of materials are discussed below with reference to FIGS. 9-15, 16A-16B, and 17A-17B, intermediate materials may be included in the gate stacks 900 of the transistors 920 as discussed above with reference to FIG. 9. Note that FIGS. 9-15, 16A-16B, and 17A-17B are intended to show relative arrangements of the components therein, and that transistors 920 may include other components that are not illustrated (e.g., electrical contacts to the source region 916 and the drain region 918 to transport current in and out of the transistors 920). Although various components of the transistors 920 are illustrated in FIGS. 9-15, 16A-16B, and 17A-17B as being planar rectangles or formed of rectangular solids, this is simply for ease of illustration, and embodiments of these transistors 920 may be curved, rounded, or otherwise irregularly shaped as dictated by the manufacturing processes used to fabricate the transistors 920.

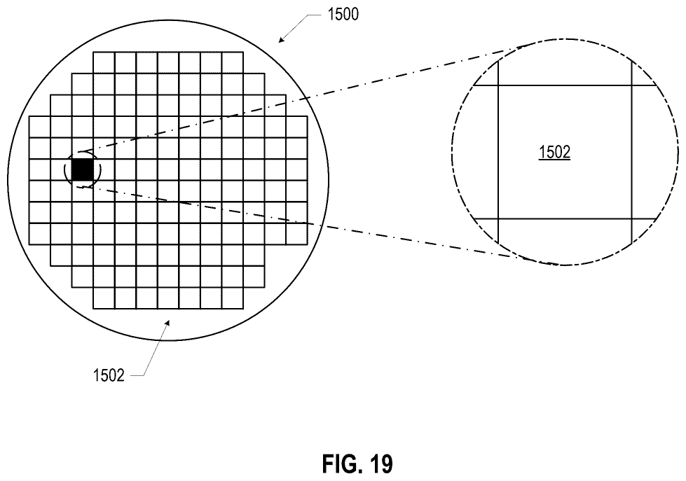

FIG. 10 depicts a transistor 920 including a transistor gate stack 900 and having a single “top” gate provided by the gate electrode material 908. The gate dielectric stack 910 may be disposed between the gate electrode material 908 and the channel material 902. In the embodiment of FIG. 10, the gate stack 900 is shown as disposed on a support 922. The support 922 may be any structure, e.g., a substrate, a die, a wafer, or a chip, on which the gate stack 900, or other elements of the transistor 920, is disposed. The support 922 may, e.g., be the wafer 1500 of FIG. 19, discussed below, and may be, or be included in, a die, e.g., the singulated die 1502 of FIG. 19, discussed below. In some embodiments, the support 922 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 922 may be a printed circuit board (PCB) substrate, a package substrate, an interposer, a wafer, or a die. In some embodiments, the support 922 may include an insulating layer, such as an oxide isolation layer. For example, in the embodiments of FIGS. 10 and 11, the support 922 may include a semiconductor material and an ILD disposed between the semiconductor material and the source region 916, the channel material 902, and the drain region 918, to electrically isolate the semiconductor material of the support 922 from the source region 916, the channel material 902, and the drain region 918 (and thereby mitigate the likelihood that a conductive pathway will form between the source region 916 and the drain region 918 through the support 922). Examples of ILDs that may be included in a support 922 in some embodiments may include silicon oxide, silicon nitride, aluminum oxide, and/or silicon oxynitride. Any suitable ones of the embodiments of the support 922 described with reference to FIG. 10 may be used for the substrates of others of the transistors disclosed herein.

As noted above, the transistor 920 may include a source region 916 and a drain region 918 disposed on the support 922, with the channel material 902 disposed between the source region 916 and the drain region 918 so that at least some of the channel material 902 is coplanar with at least some of the source region 916 and the drain region 918. The source region 916 and the drain region 918 may have a thickness 924, and the channel material 902 may have a thickness 926. The thickness 926 may take the form of any of the embodiments of the thickness 913 discussed above with reference to FIG. 9. In some embodiments, the thickness 924 may be less than the thickness 926 (as illustrated in FIG. 10, with the source region 916 and the drain region 918 each disposed between some of the channel material 902 and the support 922), while in other embodiments, the thickness 924 may be equal to the thickness 926. In some embodiments, the channel material 902, the high-k dielectric 906, and/or the gate electrode material 908 may conform around the source region 916 and/or the drain region 918. The source region 916 and the drain region 918 may be spaced apart by a distance 925 that is the gate length of the transistor 920. In some embodiments, the gate length may be between about 5 and 40 nanometers, including all values and ranges therein (e.g., between about 22 and 35 nanometers, or between about 20 and 30 nanometers).

The source region 916 and the drain region 918 may be highly doped semiconductors, e.g., with dopant concentrations of about 1021 dopants per cubic centimeter (cm⁻³), in order to advantageously form Ohmic contacts with the respective source or drain contacts (not shown in FIG. 9), although these regions may also have lower dopant concentrations and may form Schottky contacts in some implementations. Irrespective of the exact doping levels, the source region 916 and the drain region 918 of a transistor are the regions having dopant concentration higher than in other regions, e.g., higher than a dopant concentration in the transistor channel (i.e., in a channel material extending between the source region 916 and the drain region 918), and, therefore, may be referred to as “highly doped” (HD) regions. Even when doped to realize threshold voltage tuning as described herein, the channel portions of transistors typically include semiconductor materials with doping concentrations significantly smaller than those of the source region 916 and the drain region 918.

The source region 916 and the drain region 918 of the transistor 920 may generally be formed using either an implantation/diffusion process or an etching/deposition process. In the former process, dopants such as boron, aluminum, antimony, phosphorous, or arsenic may be ion-implanted into the channel material 902 to form the source and drain regions. An annealing process that activates the dopants and causes them to diffuse further into the channel material 902 may follow the ion implantation process. In the latter process, portions of the channel material 902 may first be etched to form recesses at the locations of the future source region 916 and drain region 918. An epitaxial deposition process may then be carried out to fill the recesses with material that is used to fabricate the source region 916 and the drain region 918. In some implementations, the source region 916 and the drain region 918 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 916 and the drain region 918 may be formed using one or more alternate semiconductor materials such as germanium or a group III-V material or alloy. And in further embodiments, one or more layers of metal and/or metal alloys may be used to form the source region 916 and the drain region 918. Because, as is common in the field of FETs, designations of source and drain are often interchangeable, the source region 916 and the drain region 918 of the transistor 920 may simply be referred to herein as a first source or drain (S/D) region and a second S/D region.

FIG. 11 depicts a transistor 920 including a transistor gate stack 900 and having a single “top” gate provided by the gate electrode material 908. The gate dielectric stack 910 may be disposed between the gate electrode material 908 and the channel material 902. In the embodiment of FIG. 11, the gate stack 900 is shown as disposed on a support 922. The transistor 920 may include a source region 916 and a drain region 918 disposed on the support 922, with the insulator material 904 disposed between the source region 916 and the drain region 918 so that at least some of the insulator material 904 is coplanar with at least some of the source region 916 and the drain region 918. As discussed above, in some embodiments, the support 922 of FIG. 11 may include a semiconductor material and ILD disposed between the semiconductor material and the source region 916, the channel material 902, and the drain region 918, to electrically isolate the semiconductor material of the support 922 from the source region 916, the channel material 902, and the drain region 918. In some embodiments, the high-k dielectric 906, and/or the gate electrode material 908 may conform around the source region 916 and/or the drain region 918.

FIG. 12 depicts a transistor 920 including a transistor gate stack 900 and having a single “bottom” gate. The gate dielectric stack 910 may be disposed between the gate electrode material 908 and the channel material 902. In the embodiment of FIG. 12, the gate stack 900 is shown as disposed on a support 922 in an orientation “upside down” to the one illustrated in FIG. 10; that is, the gate electrode material 908 may be disposed between the support 922 and the channel material 902. The transistor 920 may include a source region 916 and a drain region 918 disposed on the channel material 902 such that the source region 916 and the drain region 918 are not coplanar with the channel material 902.

FIG. 13 depicts a transistor 920 including a transistor gate stack 900 and having a single “bottom” gate. The gate dielectric stack 910 may be disposed between the gate electrode material 908 and the channel material 902. In the embodiment of FIG. 13, the gate stack 900 is shown as disposed on a support 922 in an orientation “upside down” to the one illustrated in FIG. 10; that is, the gate electrode material 908 may be disposed between the support 922 and the channel material 902. The transistor 920 may include a source region 916 and a drain region 918 disposed on the channel material 902 such that at least some of the source region 916 and at least some of the drain region 918 are coplanar with at least some of the channel material 902. In some embodiments, the source region 916 and the drain region 918 may each be disposed between some of the channel material 902 and the support 922, as illustrated in FIG. 13, while in other embodiments, the channel material 902 may not extend “above” the source region 916 or the drain region 918. In some embodiments, the channel material 902 may conform around the source region 916 and/or the drain region 918.

FIG. 14 depicts a double-gate transistor 920 including two transistor gate stacks 900-1 and 900-2 and having “bottom” and “top” gates provided by the gate electrode material 908-1/gate dielectric stack 910-1 and the gate electrode material 908-2/gate dielectric stack 910-2, respectively. The gate dielectric stacks 910-1 and 910-2 may include high-k dielectrics 906-1 and 906-2, and insulator materials 904-1 and 904-2, respectively. Each gate dielectric stack 910 may be disposed between the corresponding gate electrode material 908 and the channel material 902. In other examples, the insulator materials 904-1, 904-2 may be absent. Each gate dielectric stack 910 may be disposed between the corresponding gate electrode material 908 and the channel material 902. The transistor 920 may include a source region 916 and a drain region 918 disposed proximate to the channel material 902. In the embodiment illustrated in FIG. 14, the source region 916 and the drain region 918 are disposed on the insulator material 904-2, and the high-k dielectric 906-2 is disposed conformably around the source region 916, the insulator material 904-2, and the drain region 918. The gate electrode material 908-2 is disposed on the high-k dielectric 906-2. In the embodiment of FIG. 14, at least some of the source region 916 and at least some of the drain region 918 are coplanar with at least some of the high-k dielectric 906-2.

FIG. 15 depicts a double-gate transistor 920 including two transistor gate stacks 900-1 and 900-2 and having “bottom” and “top” gates provided by the gate electrode material 908-1/gate dielectric stack 910-1 and the gate electrode material 908-2/gate dielectric stack 910-2, respectively. Each gate dielectric stack 910 may include a high-k dielectric 906. Each gate dielectric stack 910 may be disposed between the corresponding gate electrode material 908 and the channel material 902. The transistor 920 may include a source region 916 and a drain region 918 disposed proximate to the channel material 902. In the embodiment illustrated in FIG. 15, the source region 916 and the drain region 918 are coplanar with the channel material 902, and disposed between the high-k dielectrics 906-1 and 906-2. The relative arrangement of the source region 916, the drain region 918, and the channel material 902 may take the form of any of the embodiments discussed above with reference to FIG. 10.

FIGS. 16A and 16B are perspective and cross-sectional side views, respectively, of an example tri-gate transistor 920 including a transistor gate stack 900, in accordance with various embodiments. The transistor 920 of FIGS. 16A and 16B may include a channel material 902, and a gate stack 900 including a gate electrode material 908, and a high-k dielectric 906. In the tri-gate transistor 920 illustrated in FIGS. 16A and 16B, a fin 932 formed of a semiconductor material may extend from a base 940 of the semiconductor material. An oxide material 930 may be disposed on either side of the fin 932. In some embodiments, the oxide material 930 may include any of the materials discussed herein with reference to the high-k dielectric 906.

The gate stack 900 may wrap around the fin 932 as shown, with the channel material 902 corresponding to the portion of the fin 932 wrapped by the gate stack 900. The fin 932 may include a source region 916 and a drain region 918 on either side of the gate stack 900, as shown. The composition of the channel material 902, the source region 916, and a drain region 918 may take the form of any of the embodiments disclosed herein, or known in the art. Although the fin 932 illustrated in FIGS. 16A and 16B is shown as having a rectangular cross-section, the fin 932 may instead have a cross-section that is rounded or sloped at the “top” of the fin 932, and the gate stack 900 may conform to this rounded or sloped fin 932. In use, the tri-gate transistor 920 may form conducting channels on three “sides” of the fin 932, potentially improving performance relative to single-gate transistors (which may form conducting channels on one “side” of the channel material 902) and double-gate transistors (which may form conducting channels on two “sides” of the channel material 902).

FIGS. 17A and 17B are perspective and cross-sectional side views, respectively, of an example all-around gate transistor 920 including a transistor gate stack 900, in accordance with various embodiments. The transistor 920 of FIGS. 17A and 17B may include a channel material 902, and a gate stack 900 including a gate electrode material 908, and a high-k dielectric 906. In the all-around gate transistor 920 illustrated in FIGS. 17A and 17B, a wire 936 formed of a semiconductor material may extend above a substrate 934 and a layer of oxide material 930. The wire 936 may take the form of a nanowire or nanoribbon, for example. The gate stack 900 may wrap entirely or almost entirely around the wire 936, as shown, with the channel material 902 corresponding to the portion of the wire 936 wrapped by the gate stack 900. In particular, the high-k dielectric 906 may wrap around the channel material 902 of the fin 932, and the gate electrode material 908 may wrap around the high-k dielectric 906. In some embodiments, the gate stack 900 may fully encircle the wire 936. The wire 936 may include a source region 916 and a drain region 918 on either side of the gate stack 900, as shown. The composition of the channel material 902, the source region 916, and a drain region 918 may take the form of any of the embodiments disclosed herein, or known in the art. Although the wire 936 illustrated in FIGS. 17A and 17B is shown as having a rectangular cross-section, the wire 936 may instead have a cross-section that is rounded or otherwise irregularly shaped, and the gate stack 900 may conform to the shape of the wire 936. In use, the tri-gate transistor 920 may form conducting channels on more than three “sides” of the wire 936, potentially improving performance relative to tri-gate transistors. Although FIGS. 17A and 17B depict an embodiment in which the longitudinal axis of the wire 936 runs substantially parallel to a plane of the oxide material 930 (and a plane of the substrate 934), this need not be the case; in other embodiments, for example, the wire 936 may be oriented “vertically” so as to be perpendicular to a plane of the oxide 930 (or plane of the substrate 934).

FIGS. 18A-18C provide various views of an example IC device 1800 that may be used to implement a hysteretic memory cell with a vertical transistor 1820, according to some embodiments of the present disclosure. In particular, FIG. 18B illustrates a cross-section of the IC device 1800 taken along the section/plane B-B of FIGS. 18A and 18C, and FIG. 18C illustrates a cross-section of the IC device 1800 taken along the section/plane C-C of FIG. 18A, while FIG. 18A illustrates a cross-section of the IC device 1800 taken along the section/plane A-A of FIGS. 18B and 18C. With reference to an example coordinate system x-y-z that may be used to provide different views of an IC device, FIGS. 18A and 18C provide cross-sectional side views across planes x-z and y-z, respectively, while FIG. 18B provides a top-down view across a plane x-y, with a number of components not shown in the top-down view of FIG. 18B to more readily illustrate how the gate of the transistor 1820 of the IC device 1800 may be arranged.

As shown in FIG. 18, the IC device 1800 includes a support structure 1802, over which the transistor 1820 may be provided. In general, implementations of the present disclosure may be formed or carried out on a substrate, such as a semiconductor substrate composed of semiconductor material systems including, for example, N-type or P-type materials systems. The support structure 1802 may be an example of a substrate discussed above with respect to FIG. 10.

A portion of the IC device 1800 within a rectangular dashed contour shown in FIG. 18A indicates an approximate outline of the transistor 1820. As shown in FIG. 18, the transistor 1820 may include a gate electrode material 1804, a channel material 1806, and a pair of S/D regions 1808 provided in the channel material 1806. As also shown in FIG. 18, a gate insulator material 1810 may be integrated with the gate of the transistor 1820 by being provided between the gate electrode material 1804 and the channel material 1806. FIG. 18 further illustrates an insulator material 1812 that may surround various portions of the transistor 1820 to provide electrical isolation between portions of the IC device 1800. FIG. 18 also illustrates a bitline 1840, a wordline 1850, and a plateline 1860. As shown in FIG. 18, the wordline 1850 is electrically coupled to (e.g., in conductive contact with) the gate electrode material 1804 of the transistor 1820 (e.g., in some embodiments, the wordline 1850 may serve as a contact to the gate of the transistor 1820), but is electrically separated from the channel material 1806 by means of a spacer material 1814. As also shown in FIG. 18, the plateline 1860 is electrically coupled to (e.g., in conductive contact with) the first S/D region 1808-1 of the pair of the S/D regions 1808 of the transistor 1820 (e.g., in some embodiments, the plateline 1860 may serve as a contact to the first S/D region 1808-1). FIG. 18 further illustrates that the bitline 1840 is electrically coupled to (e.g., in conductive contact with) the second S/D region 1808-2 of the pair of the S/D regions 1808 of the transistor 1820 (e.g., in some embodiments, the bitline may serve as a contact to the second S/D region 1808-2). The transistor 1820 may be an example of the transistors 130B-1-130B-N, described above with respect to FIG. 1B.

The gate electrode material 1804 may include at least one P-type work function metal or N-type work function metal, depending on whether the transistor 1820 is a PMOS transistor or an NMOS transistor (P-type work function metal used as a gate electrode material when the transistor 1820 is a PMOS transistor and N-type work function metal used as a gate electrode material when the transistor 1820 is an NMOS transistor). For a PMOS transistor, metals that may be used for the gate electrode material 1804 may include, but are not limited to, ruthenium, palladium, platinum, cobalt, nickel, and conductive metal oxides (e.g., ruthenium oxide). For an NMOS transistor, metals that may be used for a gate electrode material 1804 may include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, a gate electrode material 1804 may include a stack of two or more metal layers, where one or more metal layers are work function metal layers and at least one metal layer is a fill metal layer. Further layers may be included next to a gate electrode material 1804 for other purposes, such as to act as a diffusion barrier layer or/and an adhesion layer.

The channel material 1806 may be composed of semiconductor material systems including, for example, N-type or P-type materials systems. In particular, the channel material 1806 may be formed of a thin-film material. Some such materials may be deposited at relatively low temperatures, which allows depositing them within the thermal budgets imposed on back end fabrication to avoid damaging the frontend components (not specifically shown in FIG. 18) of the IC device 1800. In some embodiments, the channel material 1806 may have a thickness between about 1 and 75 nanometers, e.g., between about 1 nanometers and 10 nanometers or between about 5 nanometers and 30 nanometers, including all values and ranges therein. In some embodiments, the channel material 1806 may include a high mobility oxide semiconductor material, such as tin oxide, antimony oxide, indium oxide, indium tin oxide, titanium oxide, zinc oxide, indium zinc oxide, IGZO, gallium oxide, titanium oxynitride, ruthenium oxide, or tungsten oxide. In general, the channel material 1806 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous, polymorphous, or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

Whether the channel material 1806 is a thin-film channel material, as opposed to an epitaxially grown semiconductor material that may be included in the IC device by layer transfer, may be identified by inspecting grain size of the channel material 1806. An average grain size of the channel material 1806 being between about 0.5 and 1 millimeters (in which case the material may be considered to be polycrystalline) or smaller than about 0.5 millimeter (in which case the material may be considered to be polymorphous or amorphous) may be indicative of the channel material 1806 being a thin-film material deposited onto portions of the IC device 1800 and not epitaxially grown. On the other hand, an average grain size of the channel material 1806 being equal to or greater than about 1 millimeter (in which case the material may be considered to be a single-crystalline material) may be indicative of the channel material 1806 having been included in the IC device 1800 by layer transfer. In the embodiments where the channel material 1806 is a single-crystalline semiconductor material, it may include any of the materials described above that may be provided in a single-crystalline form.

As described above, S/D regions 1808 may be regions of doped semiconductors, e.g., regions of a doped channel material, so as to supply charge carriers for the transistor channel. The S/D regions 1808 may generally be formed using either an implantation/diffusion process or an etching/deposition process. In the former process, dopants such as boron, aluminum, antimony, phosphorous, or arsenic may be ion-implanted into the channel material to form the S/D regions 1808 in the channel material 1806. An annealing process that activates the dopants and causes them to diffuse further into the channel material 1806 typically follows the ion implantation process. In the latter process, the channel material 1806 may first be etched to form recesses at the locations of the S/D regions 1808. An epitaxial deposition process may then be carried out to fill the recesses with material that is used to fabricate the S/D regions 1808. In some implementations, the S/D regions 1808 may be fabricated using a silicon alloy such as silicon germanium or silicon carbide. In some implementations the epitaxially deposited silicon alloy may be doped in situ with dopants such as boron, arsenic, or phosphorous. In further embodiments, the S/D regions 1808 may be formed using one or more alternate semiconductor materials such as germanium or a group III-V material or alloy. And in further embodiments, one or more layers of metal and/or metal alloys may be used to form the S/D regions 1808.

The gate insulator material 1810 is provided between the gate electrode material 1804 and the channel material 1806. In some embodiments, the gate insulator material 1810 may be a high-k dielectric material typically used in logic transistors and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric material of the IC device 1800 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, scandium aluminum nitride, tantalum oxide, tantalum silicon oxide, lead scandium tantalum oxide, and lead zinc niobate. In some embodiments, an annealing process may be carried out on the gate dielectric material during manufacture of the IC device 1800 to improve the quality of the gate dielectric. In some embodiments, the gate dielectric included in the gate stack of the transistor 1820 may have a thickness between about 0.5 nanometers and 3 nanometers, including all values and ranges therein, e.g., between about 1 and 3 nanometers, or between about 1 and 2 nanometers. In some embodiments, the gate insulator material 1810 may include a hysteretic element as described above, instead of, or in addition to, a high-k dielectric material as used in logic transistors.

Although also not shown in the present drawings, in some embodiments of the IC device 1800, the transistor 1820 may further include an intermediate material between at least a portion of the gate insulator material 1810 and at least a portion of the channel material 1806. Such an intermediate material may include any non-conductive material, and may be provided to address endurance issues that may arise due to charging at the interface between the gate insulator material 1810 and the channel material 1806 that may take place if the gate insulator material 1810 directly interfaces the channel material 1806.

The insulator material 1812 may include any suitable ILD material for providing electrical isolation between portions of the IC device 1800. In various embodiments, the insulator material 1812 may include materials such as silicon oxide, carbon-doped silicon oxide, silicon carbide, silicon nitride, silicon oxynitride, aluminum oxide, organic polymers such as perfluorocyclobutane or polytetrafluoroethylene, fluorosilicate glass (FSG), and organosilicates such as silsesquioxane, siloxane, or organosilicate glass. In some embodiments, the insulator material 1812 may be a low-k dielectric. In some embodiments, the insulator material 1812 may include pores or air gaps to further reduce its dielectric constant. The spacer material 1814 may also include any such ILD material for providing electrical isolation between the wordline 1850 and the channel material 1806.

Turning to the details of the vertical nature of the transistor 1820, as shown in FIG. 18, each of the channel material 1806 and the gate insulator material 1810 includes portions that may be referred to as “sidewall portions” because they are substantially perpendicular to the support structure 1802. As further shown in FIG. 18, each of the channel material 1806 and the gate insulator material 1810 includes a portion that may be referred to as a “middle horizontal portion” because it is in between the sidewall portions (i.e., in the middle) and is substantially parallel to the support structure 1802 (such a portion may also be referred to as a “bottom portion” or, simply, a “bottom” because it is at the bottom of the opening in the insulator material 1812, i.e., closest to the support structure 1802). The first and second sidewall portions of the channel material 1806 are labeled in FIG. 18 as, respectively, portions 1816-1 and 1816-2, and the middle horizontal portion of the channel material 1806 is labeled in FIG. 18 as a portion 1816-3. Similarly, the first and second sidewall portions of the gate insulator material 1810 are labeled in FIG. 18 as, respectively, portions 1822-1 and 1822-2, and the middle horizontal portion of the gate insulator material 1810 is labeled in FIG. 18 as a portion 1822-3. As shown in FIG. 18, the middle horizontal portion 1822-3 is between the middle horizontal portion 1816-3 and the gate electrode material 1804, the first sidewall portion 1822-1 is between the first sidewall portion 1816-1 and the gate electrode material 1804, and the second sidewall portion 1822-2 is between the second sidewall portion 1816-2 and the gate electrode material 1804.

The different portions 1816-1, 1816-2, 1816-3 of the channel material 1806 form a continuous layer of the channel material 1806, starting from the first sidewall portion 1816-1, continuing with the middle horizontal portion 1816-3, and further continuing with the second sidewall portion 1816-2. Thus, a continuous channel region is provided between the first S/D region 1808-1 and the second S/D region 1808-2. Similarly, the different portions 1822 of the gate insulator material 1810 form a continuous layer of the gate insulator material 1810, starting from the first sidewall portion 1822-1, continuing with the middle horizontal portion 1822-3, and further continuing with the second sidewall portion 1822-2. Thus, the gate insulator material 1810 is provided continuously along the channel material 1806, between the channel material 1806 and the gate electrode material 1804, where the channel material 1806 may be conformal to the shape of the gate insulator material 1810.

As shown in FIG. 18, the gate insulator material 1810 is non-planar in that it includes bends/corners. In particular, each of the gate insulator material 1810 and the channel material 1806 of the IC device 1800 may be seen as a U-shaped structure. The IC device 1800 may then be described as having a gate that includes a U-shaped structure of the gate insulator material 1810. Because the channel material 1806 is conformal to the shape of the gate insulator material 1810, the channel material 1806 is non-planar as well and includes bends/corners corresponding to those of the gate insulator material 1810. In regions where the gate insulator material 1810 bends (i.e., at the corners of the gate insulator material 1810), the electric field may be higher and, therefore, it may be easier to switch the memory state of the gate insulator material 1810 if the gate insulator material 1810 includes the hysteretic element.

The transistor 1820 as shown in FIG. 18 is a vertical transistor because the first S/D contact, provided by one of the control lines (e.g., the plateline 1860) is at the bottom of the transistor 1820 (i.e., closer to the support structure 1802), while the second S/D contact, provided by another one of the control lines (e.g., the bitline 1840) is proximate to the top of the transistor 1820 (i.e., further away from the support structure 1802). Although the example illustrated in FIGS. 18A-18B depict the gate electrode material 1804 as being coupled with a wordline 1850 that is substantially parallel with the support 1802, in another example in which the transistor 1820 is used as a gain/sense transistor for a memory array (e.g., such as the vertical transistors 130B-1-130B-N of FIG. 1B), a control line may be coupled with the gate electrode material 1804.

FIGS. 19-24 illustrate various examples of apparatuses that may include one or more of the IC structures with a memory array and shared gain elements as disclosed herein.

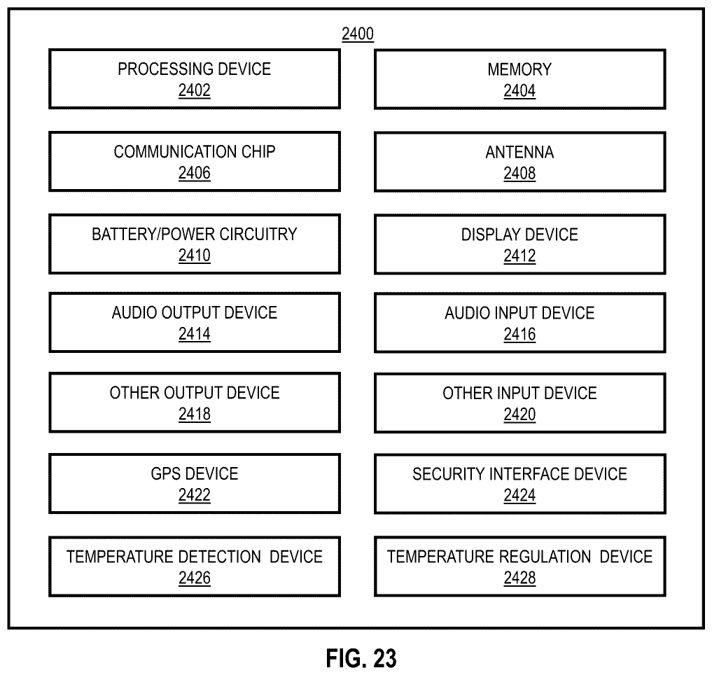

FIG. 19 is a top view of a wafer 1500 and dies 1502 that may include one or more IC structures with a memory array and shared gain elements in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random-access memory (RAM) device, such as a static RAM (SRAM) device, dynamic RAM (DRAM) a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 2402 of FIG. 23) or other logic that is configured to store information in the memory devices or execute instructions stored in the memory array.

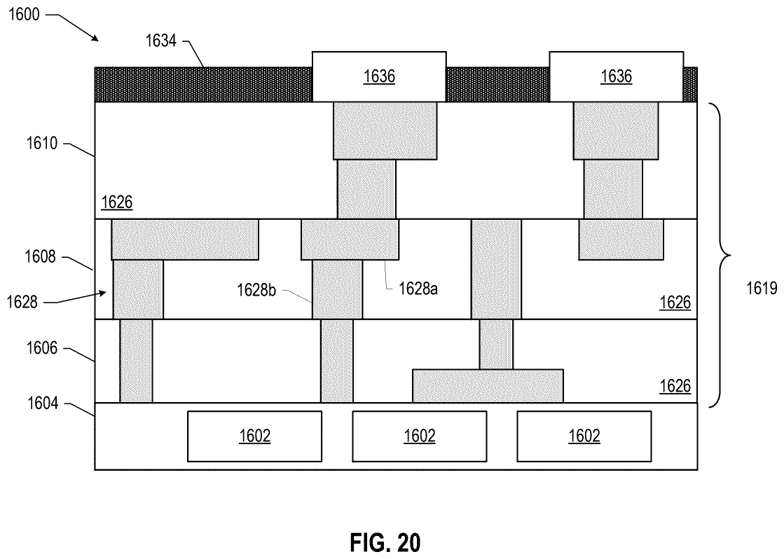

FIG. 20 is a side, cross-sectional view of an IC device 1600 that may include one or more IC structures in accordance with any of the embodiments disclosed herein. One or more of the IC devices 1600 may be included in one or more dies 1502 (FIG. 19). The IC device 1600 may include a device region 1604. The device region 1604 may further include electrical contacts to the gate and S/D contacts of the transistors included in the device region 1604.

Electrical signals, such as power and/or input/output (I/O) signals, may be routed to and/or from the devices (e.g., the transistors) of the device region 1604 through one or more interconnect layers disposed on the device region 1604 (illustrated in FIG. 20 as interconnect layers 1606, 1608, and 1610). For example, electrically conductive features of the device region 1604 may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606, 1608, and 1610 to route electrical signals according to a wide variety of designs (in particular, the arrangement is not limited to the particular configuration of interconnect structures 1628 depicted in FIG. 20). Although a particular number of interconnect layers 1606, 1608, and 1610 is depicted in FIG. 20, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the support upon which the device region 1604 is formed. For example, the lines 1628a may route electrical signals in a direction in and out of the page from the perspective of FIG. 20. The vias 1628b may be arranged to route electrical signals in a direction of a plane that is substantially perpendicular to the surface of the support upon which the device region 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 20. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions of the IC structures described herein) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606, 1608, and 1610. In FIG. 20, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components. The device region may include devices 1602, which may include memory devices and/or shared gain elements in accordance with examples described herein.

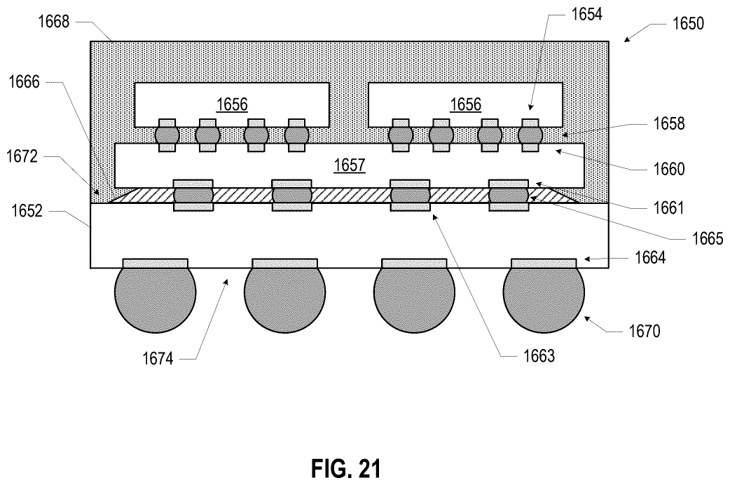

FIG. 21 is a side, cross-sectional view of an example IC package 1650 that may include one or more IC structures with a memory array and shared gain elements in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 20.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 21 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 21 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

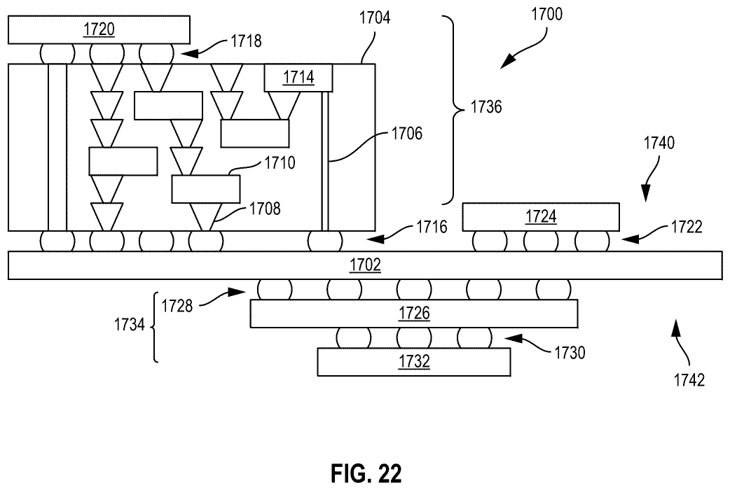

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 21 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 22.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 21 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 21, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 22 is a side, cross-sectional view of an IC device assembly 1700 that may include one or more IC packages or other electronic components (e.g., a die) including one or more IC structures with a memory array and shared gain elements in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 21 (e.g., may include one or more IC structures in accordance with embodiments described herein).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 22 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 22), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 22, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 19), an IC device (e.g., the IC device 1600 of FIG. 20), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 22, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 22 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 23 is a block diagram of an example computing device 2400 that may include one or more components including one or more IC devices with a memory array and shared gain elements in accordance with any of the embodiments disclosed herein. For example, any suitable ones of the components of the computing device 2400 may include a die (e.g., the die 1502 of FIG. 19) having a memory array with shared gain elements as described herein. Any one or more of the components of the computing device 2400 may include, or be included in, an IC package 1650 of FIG. 21 or an IC device 1700 of FIG. 22.

A number of components are illustrated in FIG. 23 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 23, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

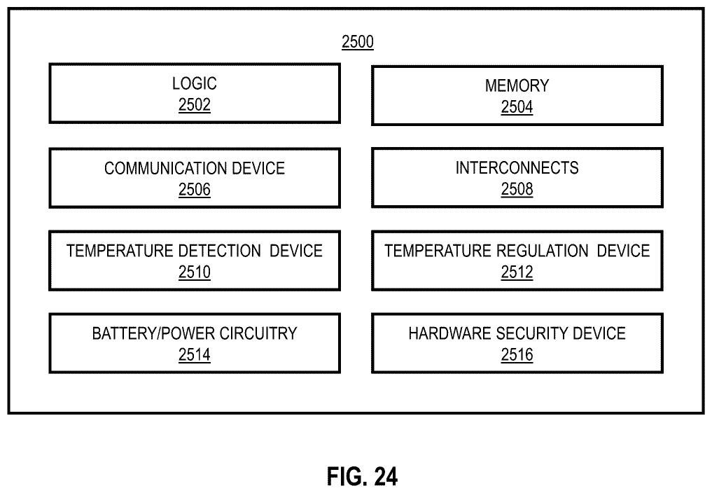

FIG. 24 is a block diagram of an example processing device 2500 that may include one or more IC devices with a memory array and shared gain elements in accordance with any of the embodiments disclosed herein. For example, any suitable ones of the components of the processing device 2500 may include a die (e.g., the die 1502 of FIG. 19) having a memory array and shared gain elements as described herein. Any one or more of the components of the processing device 2500 may include, or be included in, an IC device 1600 (FIG. 20). Any one or more of the components of the processing device 2500 may include, or be included in, an IC package 1650 of FIG. 21 or an IC device 1700 of FIG. 22. Any one or more of the components of the processing device 2500 may include, or be included in, a computing device 2400 of FIG. 23; for example, the processing device 2500 may be the processing device 2402 of the computing device 2400.

A number of components are illustrated in FIG. 24 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 24, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 23). In some embodiments, the memory 2504 may be a designated device configured to provide storage functionality for the components of the processing device 2500 (i.e., local), while the memory 2404 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 23). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 23 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 23 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 23. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 23. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC structure, including a first memory cell and a second memory cell, where the first memory cell includes a first transistor with a first source or drain terminal and a first gate terminal, and the second memory cell includes a second transistor; a first control line (e.g., first conductive line) coupled with a gate terminal of the first transistor; a second control line (e.g., second conductive line) coupled with a gate terminal of the second transistor; a third control line (e.g., third conductive line) coupled with a source or drain terminal of the first transistor and a source or drain terminal of the second transistor; and a third transistor, where the third transistor includes a gate terminal coupled with the third control line.

Example 2 provides the IC structure of example 1, where: the third transistor includes a third source or drain terminal coupled with a sense amplifier.

Example 3 provides the IC structure of example 1, further including a substrate, where: the first memory cell is stacked over the second memory cell over the substrate; and the third control line is substantially orthogonal to the substrate.

Example 4 provides the IC structure of example 1, further including a substrate; and an interconnect layer over the substrate, where the first memory cell and the second memory cell are over the interconnect layer.

Example 5 provides the IC structure of example 4, where: the third transistor is over the interconnect layer.

Example 6 provides the IC structure of example 4, where: the third transistor is a frontend transistor between the substrate and the interconnect layer.

Example 7 provides the IC structure of example 1, further including a substrate; and an interconnect layer over the substrate, where the first memory cell and the second memory cell are between the substrate and the interconnect layer, and where the third transistor is over the interconnect layer.

Example 8 provides the IC structure of example 1, further including a substrate; and an interconnect layer over the substrate, where the first memory cell, the second memory cell, and the third transistor are between the substrate and the interconnect layer.

Example 9 provides the IC structure of example 1, where: the first memory cell and the second memory cell each include a ferroelectric or an antiferroelectric capacitor.

Example 10 provides an IC structure, including a FEOL layer; a BEOL layer over the FEOL layer; and a plurality of memory cells over the BEOL layer; a control line coupled with the plurality of memory cells; and a gain element including a transistor, where the control line is coupled with a gate stack of the transistor of the gain element.

Example 11 provides the IC structure of example 10, where: the plurality of memory cells include a first memory cell and a second memory cell in a layer over the first memory cell; and the control line is coupled with the first memory cell and the second memory cell.

Example 12 provides the IC structure of any one of examples 10-11, where: the transistor includes a source or drain terminal coupled with a sensing circuit.

Example 13 provides the IC structure of any one of examples 10-12, where: the BEOL layer is a first BEOL layer including conductive interconnects; and the IC structure further includes a second BEOL layer over the first BEOL layer, where the second BEOL layer includes the gain element, and a third BEOL layer over the second BEOL layer, where the third BEOL layer includes a memory cell of the plurality of memory cells.

Example 14 provides the IC structure of any one of examples 10-13, where: the FEOL layer includes the gain element.

Example 15 provides the IC structure of any one of examples 10-14, where: the control line is a first control line; the transistor is a first transistor; and the memory cell includes a second transistor including a second gate stack and a source or drain region, where: the gate stack of the second transistor is coupled with a second control line, and the source or drain region is coupled with the first control line.

Example 16 provides the IC structure of example 15, where: the source or drain region of the second transistor is a first source or drain region; the second transistor includes a second source or drain region; and the second source or drain region is coupled with one or more capacitors.

Example 17 provides an IC device, including a substrate; an interconnect layer over the substrate; an array of memory cells over the interconnect layer, including a plurality of memory cells stacked over one another in a plurality of layers over the interconnect layer; a plurality of transistors between the array of memory cells and sense circuitry, where an individual transistor of the plurality of transistors includes a gate terminal; and a plurality of control lines extending through the plurality of layers along an axis substantially orthogonal to the substrate, where an individual control line of the plurality of control lines is coupled with the plurality of memory cells and the gate terminal of the individual transistor.

Example 18 provides the IC device of example 17, where: the individual transistor includes a source or drain terminal coupled with the sense circuitry.

Example 19 provides the IC device of any one of examples 17-18, where: the plurality of transistors is in a layer over the interconnect layer.

Example 20 provides the IC device of any one of examples 17-18, where: the plurality of transistors is in a device region between the substrate and the interconnect layer.

Example 21 provides an IC device, including a substrate; an interconnect layer over the substrate; an array of hysteretic capacitors over the interconnect layer, the array of hysteretic capacitors including a plurality of capacitors stacked over one another; a plurality of first control lines coupled with the array of hysteretic capacitors, where the plurality of first control lines includes an individual control line that is substantially orthogonal to the substrate and coupled with the plurality of capacitors; and a plurality of transistors, where an individual transistor of the plurality of transistors includes a gate terminal coupled with the individual control line.

Example 22 provides the IC device of example 21, further including a plurality of second control lines coupled with the array, where: the plurality of second control lines are substantially parallel to the substrate, and each of the plurality of capacitors are coupled with a different one of the plurality of second control lines.

Example 23 provides the IC device of example 22, where: the plurality of first control lines are platelines; and the plurality of second control lines are bitlines.

Example 24 provides the IC device of any one of examples 21-23, where: the plurality of transistors are in a FEOL layer between the substrate and the interconnect layer.

Example 25 provides the IC device of any one of examples 21-23, where: the plurality of transistors are in a layer between the interconnect layer and the array of hysteretic capacitors.

Example 26 provides an IC structure, including a substrate; a plurality of memory cells over the substrate; a control line coupled with the plurality of memory cells; and a transistor over the substrate and coupled with the plurality of memory cells, where the transistor includes a gate terminal coupled with the control line.

Example 27 provides the IC structure of example 26, where: the transistor is a first transistor; an individual memory cell of the plurality of memory cells includes a second transistor; and the second transistor includes a source or drain terminal coupled with the control line.

Example 28 provides the IC structure of any one of examples 26-27, where: the first transistor includes a source or drain terminal coupled with a sense amplifier.

Example 29 provides the IC structure of any one of examples 26-28, where: the plurality of memory cells are stacked over one another over the substrate; and the control line is substantially orthogonal to the substrate.

Example 30 provides the IC structure of any one of examples 26-29, further including an interconnect layer over the substrate, where: the plurality of memory cells is over the interconnect layer.

Example 31 provides the IC structure of example 30, where: the transistor is over the interconnect layer.

Example 32 provides the IC structure of example 30, where: the transistor is a frontend transistor between the substrate and the interconnect layer.

Example 33 provides the IC structure of any one of examples 26-32, where: the memory cell includes one or more capacitors.

Example 34 provides the IC structure of example 33, where: the memory cell includes a ferroelectric capacitor.

Example 35 provides the IC structure according to any one of examples 1-34, where the IC structure includes or is a part of a central processing unit.

Example 36 provides the IC structure according to any one of examples 1-35, where the IC structure includes or is a part of a memory device.

Example 37 provides the IC structure according to any one of examples 1-36, where the IC structure includes or is a part of a logic circuit.

Example 38 provides the IC structure according to any one of examples 1-37, where the IC structure includes or is a part of input/output circuitry.

Example 39 provides the IC structure according to any one of examples 1-38, where the IC structure includes or is a part of a field programmable gate array transceiver.

Example 40 provides the IC structure according to any one of examples 1-39, where the IC structure includes or is a part of a field programmable gate array logic.

Example 41 provides the IC structure according to any one of examples 1-40, where the IC structure includes or is a part of a power delivery circuitry.

Example 42 provides an IC package that includes an IC die including an IC structure according to any one of examples 1-41; and a further IC component, coupled to the IC die.

Example 43 provides the IC package according to example 42, where the further IC component includes a package substrate.

Example 44 provides the IC package according to example 42, where the further IC component includes an interposer.

Example 45 provides the IC package according to example 42, where the further IC component includes a further IC die.

Example 46 provides a computing device that includes a carrier substrate and an IC structure coupled to the carrier substrate, where the IC structure is an IC structure according to any one of examples 1-41, or the IC structure is included in the IC package according to any one of claims 42-45.

Example 47 provides the computing device according to example 46, where the computing device is a wearable or handheld computing device.

Example 48 provides the computing device according to examples 46 or 47, where the computing device further includes one or more communication chips.

Example 49 provides the computing device according to any one of examples 46-48, where the computing device further includes an antenna.

Example 50 provides the computing device according to any one of examples 46-49, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first memory cell and a second memory cell, wherein the first memory cell includes a first transistor with a first source or drain terminal and a first gate terminal, and the second memory cell includes a second transistor with a second source or drain terminal and a second gate terminal;
a first conductive line coupled with the first gate terminal of the first transistor;
a second conductive line coupled with the second gate terminal of the second transistor;
a third conductive line coupled with the first source or drain terminal of the first transistor and the second source or drain terminal of the second transistor; and
a third transistor, wherein the third transistor includes a third gate terminal coupled with the third conductive line.

2. The IC structure of claim 1, wherein:
the third transistor includes a third source or drain terminal coupled with a sense amplifier.

3. The IC structure of claim 1, further comprising a substrate, wherein:
the first memory cell is stacked over the second memory cell over the substrate; and
the third conductive line is substantially orthogonal to the substrate.

4. The IC structure of claim 1, further comprising:
a substrate; and
an interconnect layer over the substrate, wherein the first memory cell and the second memory cell are over the interconnect layer.

5. The IC structure of claim 4, wherein:
the third transistor is over the interconnect layer.

6. The IC structure of claim 4, wherein:
the third transistor is a frontend transistor between the substrate and the interconnect layer.

7. The IC structure of claim 1, further comprising:
a substrate; and
an interconnect layer over the substrate, wherein the first memory cell and the second memory cell are between the substrate and the interconnect layer, and wherein the third transistor is over the interconnect layer.

8. The IC structure of claim 1, further comprising:
a substrate; and
an interconnect layer over the substrate, wherein the first memory cell, the second memory cell, and the third transistor are between the substrate and the interconnect layer.

9. The IC structure of claim 1, wherein:
the first memory cell and the second memory cell each include a ferroelectric or an antiferroelectric capacitor.

10. An integrated circuit (IC) structure, comprising:
a front-end of line (FEOL) layer;
a back end of line (BEOL) layer over the FEOL layer;
a first memory cell and a second memory cell over the BEOL layer;
a conductive line coupled with the first memory cell and the second memory cell; and
a transistor coupled with both the first memory cell and the second memory cell, wherein the conductive line is coupled with a gate of the transistor.

11. The IC structure of claim 10, wherein:
the second memory cell is in a layer over the first memory cell.

12. The IC structure of claim 10, wherein:
the transistor includes a source or drain terminal coupled with a sensing circuit.

13. The IC structure of claim 10, wherein:
the BEOL layer is a first BEOL layer including conductive interconnects; and
the IC structure further includes:
a second BEOL layer over the first BEOL layer, wherein the second BEOL layer includes the transistor, and a third BEOL layer over the second BEOL layer, wherein the third BEOL layer includes the first memory cell.

14. The IC structure of claim 10, wherein:
the FEOL layer includes the transistor.

15. The IC structure of claim 10, wherein:
the conductive line is a first conductive line; and
the first memory cell includes an access transistor including a gate and a source or drain region, wherein:
the gate of the access transistor is coupled with a second conductive line, and the source or drain region of the access transistor is coupled with the first conductive line.

16. The IC structure of claim 15, wherein:
the source or drain region of the access transistor is a first source or drain region;
the access transistor includes a second source or drain region; and
the second source or drain region is coupled with one or more capacitors.

17. An IC device, comprising:
a substrate;
an interconnect layer over the substrate;
an array of memory cells over the interconnect layer, wherein the array of memory cells includes a plurality of memory cells stacked over one another in a plurality of layers over the interconnect layer;
a plurality of transistors between the array of memory cells and sense circuitry, wherein an individual transistor of the plurality of transistors includes a gate terminal; and
a plurality of conductive lines extending through the plurality of layers along an axis substantially orthogonal to the substrate, wherein an individual conductive line of the plurality of conductive lines is coupled with the plurality of memory cells and the gate terminal of the individual transistor.

18. The IC device of claim 17, wherein:
the individual transistor includes a source or drain terminal coupled with the sense circuitry.

19. The IC device of claim 17, wherein:
the plurality of transistors is in a layer over the interconnect layer.

20. The IC device of claim 17, wherein:
the plurality of transistors is in a device region between the substrate and the interconnect layer.
